(19) United States
(12) Patent Application Publication
(10) Pub. No.: US 2018/0076376 A1
(43) Pub. Date: Mar. 15, 2018

(54) STRUCTURES, SYSTEM AND METHOD FOR CONVERTING ELECTROMAGNETIC RADIATION TO ELECTRICAL ENERGY USING METAMATERIALS, RECTENNAS AND COMPENSATION STRUCTURES

(71) Applicants: Patrick K. Brady, Glen Ellyn, IL (US); Scott Brad Herner, Lafayette, CO (US); Dale K. Kotter, Shelley, ID (US); Wounjhang Park, Superior, CO (US); Pallab Midya, Schaumberg, IL (US)

(72) Inventors: Patrick K. Brady, Glen Ellyn, IL (US); Scott Brad Herner, Lafayette, CO (US); Dale K. Kotter, Shelley, ID (US); Wounjhang Park, Superior, CO (US); Pallab Midya, Schaumberg, IL (US)

(21) Appl. No.: 15/705,164

(22) Filed: Sep. 14, 2017

Related U.S. Application Data
(60) Provisional application No. 62/394,679, filed on Sep. 14, 2016.

(51) Int. Cl. H01L 35/32; H01Q 1/22; H01L 35/22; H01L 35/02

(52) U.S. Cl. CPC H01L 35/32; H01L 35/02; H01L 35/22; H01Q 1/22

(57) ABSTRACT

A metamaterial coupled antenna includes a metamaterial and a rectenna that has an antenna element and a diode coupled by a transmission line. The metamaterial generates a spoof surface plasmon in the presence of heat. The antenna element resonates in the presence of the spoof surface plasmon as terahertz frequencies and generates a voltage that is coupled to the diode via the transmission line. The diode rectifies the voltage to produce electricity. The transmission line is configured to provide a voltage boost to the voltage signal delivered by the antenna element and to compensation for diode capacitance.

The present application claims the benefit of U.S. Provisional App. No. 62/394,679, filed Sep. 14, 2016, which is hereby incorporated by reference herein in its entirety.

### BACKGROUND

### Field of the Invention

Embodiments of the present invention relate generally to structures and methods for harvesting energy from electromagnetic radiation. More specifically, embodiments relate to systems for harvesting energy from, for example, the infrared and near infrared (such as heat) and visible spectrums and capturing terahertz energy.

### Background of the Invention

There is a great need for inexpensive renewable energy in the world. Ironically, there is an abundance of energy available in the form of sunlight and heat. Using such energy to support modern living, however, requires that energy be converted into electrical form. In fact, most electrical energy used today comes from a conversion process involving heat. For example, nuclear, coal, diesel, and natural gas powered electrical generation plants all convert naturally stored forms of energy into electricity. Unfortunately, the conversion processes used in these plants are inefficient, and often produce more heat as waste than is converted into electricity.

In addition to higher efficiency, harvesting sources of heat into usable electrical power is especially desirable at low cost. Conventional turbine-based solutions for generating electricity from heat are expensive. However, such systems have been employed for years, and are now mature. As a result, new technological solutions to convert heat to electrical power must provide sufficient improvement to overcome the status quo of turbine-based systems. Despite the maturity of turbine-based systems, high cost and greater demand for electricity make new technologies that convert heat to electricity more efficiently and at lower cost increasingly attractive. Among the new technologies being studied are thermo photovoltaic (TPV), thermoelectric (TE) and at lower temperatures organic rankine cycle (ORC).

TPV technology faces a number of hurdles in converting heat to electricity. Chief among them is that photovoltaic techniques convert short wave radiation to electricity, not the comparatively long waves of the IR and near-IR spectra associated with heat. New micron gap methods to bring this long wave energy to the operating regions of a PV cell still require conversion technology better suited to the influx of long wave radiation and thus are suitable only at the highest temperature sources.

In general, the PV cell band gap favors only energetic photons since lower energy photons do not have the energy to cross the gap. As a result, these lower energy photons are absorbed by the PV cell, and cause heat in the cell itself

Thermoelectric (TE) solutions, to date, have only been able to convert heat to electrical power at low efficiency. As a result, conventional TE solutions have not provided substantial efficiencies in energy conversion. Even so, TE has found application in automotive waste heat recovery, which further evidences the need for alternative heat-to-electric conversion technologies.

Organic Rankine Cycle (ORC) and related technologies harvest waste heat by chaining turbines together with each successive system in the chain using a lower boiling point liquid. ORC system have a number of drawbacks. They are bulky, have large numbers of moving parts, contain chemicals that are undesirable on customer sites and are limited to the properties of the liquids in the system. Ultimately, they suffer from limits of conversion time, space, and the diminishing returns of additional systems in a working space.

These and other problems with conventional techniques for harvesting electrical energy from heat require a solution with greater efficiency and lower costs.

### BRIEF SUMMARY OF THE INVENTION

In an embodiment, a system for harvesting electrical energy from electromagnetic (EM) radiation emitted by a hot source comprises a nanoantenna electromagnetic collector (NEC) film of collector/converter devices (called rectennas) that collect heat radiation emanating from a heat source, and converts that heat radiation to electrical energy. According to embodiments include rectennas comprising an antenna tuned to resonate in the presence of frequencies associated with heat, and a diode to rectify the single produced by the antenna in the presence of heat. The rectennas can be combined in various embodiments with one or more of: (1) a three dimensional (3D) metamaterial to frequency shift and compress, concentrate and make coherent the electromagnetic field; (2) THz compensation circuitry using transmission line structures to address antenna and diode impedance matching as well as created diode capacitance; and (3) metal-insulator-metal (MIM) or metal-insulator-insulator-metal (MIIM) diodes using Cobalt and its oxides with other metals such as Titanium and its oxides. The electricity generated by the rectennas in the NEC film can combined and supplied to a load for commercial purposes.

In an embodiment, a 3D metamaterial is designed to concentrate an EM field created by heat on the surface of the metamaterial. NEC devices (rectennas) are positioned in the near field directly over patterned holes (or poles) in the metamaterial overcoat of the hot body. In an embodiment, a hot gas is encased in metal as in a flue for instance. The metal casing then is the hot side material. A NEC film is then attached, metamaterial side first. Preferably, the metamaterial does not contact the rectenna. This leaves an air gap or vacuum to separate the metamaterial for reduction of heat conduction. A reflective layer is constructed and added at an offset distance. The offset distance can be calculated by simulation of the optical properties exhibited by the materials and structures at a desired frequency of NEC operation.

In an embodiment of the invention, the NEC device is a rectenna using metal-insulator-insulator-metal (MIIM) diodes constructed with Co—CoOx and TiOx—Ti although other single or double insulator diodes with equal or better performance may be used.

In an embodiment of the invention, impedance matching between the antenna elements of the NEC and the diode may be performed using a single- or multi-node tank circuit that trades current for voltage. Trading current for voltage supplies a boosted voltage to the diode. The tank circuits also matches the impedance of the rectenna antenna to a higher impedance MIM/MIIM diode. In embodiments, a compensation circuit may also be used to reduce the effects of diode capacitance. In an embodiment, the compensation circuit uses the capacitance of the MIM/MIIM device itself as part of the compensation structure. Given the very high frequency of these devices, the tank circuit and compensation structures are constructed using transmission line elements that act as either capacitors or inductors. The transmission line elements are designed using simulations of 3D EM waves in materials and structures.

The basic rectenna circuit is relatively well understood. A rectenna circuit comprises an antenna that, depending on the strength of the source, produces a small voltage (˜1 mV or less) at a high frequency (>1 THz) across a MIM or MIIM diode. Because naturally occurring sources of THz are very low power, antennas will supply far lower output voltages in those cases. In the THz range, existing semiconductor diodes cannot replenish charge carriers fast enough to keep up, that is, track the wave of voltage or current. When these oscillate too fast, the device fails to “keep up” and fails to perform its operation. . Metal-insulator-Metal diodes perform well within the THz range since, unlike the materials used in semiconductor diodes, the metals that comprise them are not charge carrier limited.

Using conventional rectennas, efficient conversion of natural THz sources is low for several reasons. The nonlinearity of the rectenna's diode's current-voltage characteristic curve occurs at a significantly higher voltage (˜100 mV) than the voltage output of the rectenna's antenna (˜1 mV or less). While the voltage location of the knee of the diode nonlinearity can be reduced, such reduction is limited by properties of the materials of the diode's elements and the ease of manufacture of the diode's elements. For instance, a MIM/MIIM diode operates by tunneling of electrons from one metal to another through the barrier of the insulator(s) separating them. The height of this barrier has a relationship to the resistance and effectiveness of tunneling of the diode. The height of a barrier is the difference of the electron affinity of the insulator(s) and the work function of the adjacent metal. Additional insulators can create asymmetry. Selection of metals with differing work functions may also add to asymmetry. Low barriers and high asymmetry are desirable since they allow low voltage tunneling.

A metric often used in diode design is responsivity. Responsivity is the ratio of the second derivative of the diode's current/voltage curve over the first derivative, and is measured in Amps/Watt. High responsivity is desirable and given the low voltage environment of rectennas in energy harvesting, a diode's responsivity value around zero (0) volts bias of the diode is a key metric.

Embodiments of the present invention implement a metal-insulator-insulator-metal (MIIM) diode with high zero bias responsivity and low resistance suitable for converting heat into electricity. MIIM diodes are most suited to convert heat to electricity over other kinds of diodes due to their high frequency (THz) capability. Previously disclosed MIIM diodes may have high zero bias responsivity but with high resistance. Low resistance in the diode enables low RC time constants, which then enables higher efficiency in converting heat to electricity. Suitable MIIM devices and fabrication methods are described in further detail herein.

Another important aspect of embodiments of the present invention is thermal management. It is important to supply a heat differential to just the collector/converter devices, and not allow the heat source to become generally cooled. To optimize heat transfer from the heat source to the collector/converter device, an embodiment of the present invention includes an optimization layer that allows cooling of the converter elements of the collector/converter devices while insulating the other areas of the surface.

In an embodiment, the optimization layer is an overcoat of two materials—one that is highly insulating and another that is highly conducting of heat. Insulating materials or vacuum are placed so as to block heat flow to regions of the NEC film that do not contain collector/converter devices. Heat conducting materials are placed so as to allow heat flow to the collector/converter devices.

Embodiments include an additional improvement to the rectenna circuit, termed “compensation circuitry.” Compensation circuits comprise passive circuit elements, such as capacitors and inductors. These elements are combined to provide a voltage boost and impedance match between the antenna and the diode. The general design is sometimes referred to as a tank circuit. Several embodiments of such compensation circuits are disclosed. For instance, single- and multi-tank compensation circuits are disclosed. An embodiment of a compensation circuit that uses the rectenna diode as the capacitor for the circuit is also disclosed.

An advantage of compensation circuits as disclosed herein is the tradeoff of antenna current for voltage. This is particularly useful because supplying a higher voltage to the diode places it in a better operating point along its current-voltage characteristic. Moreover, this tradeoff matches the low impedance of the antenna (about 100 ohms) to the higher impedance diode.

Another advantage of compensation circuits as disclosed herein is in smoothing out the shape of the voltage and current in the circuit. Compensation circuits as disclosed herein make the voltage and current curves conform to a more sinusoidal shape for more efficient power harvesting.

A second embodiment of a compensation circuit addresses the inherent capacitance of the diode. This compensation circuit is comprised of an inductor and a capacitor in parallel with the diode. Placing inductance in parallel with a capacitance cancels the imaginary component of the capacitance. As such, when properly designed this compensation circuit can solve the long RC time constant problem that has been associated with MIM and MIIM diodes.

At THz frequencies, conventional inductors (coils) cannot be used. As such, in embodiments, capacitors and inductors are created in the compensation circuits through “transmission lines” designed to appropriate dimensions. Transmission lines have unique properties of being able to exhibit either capacitance or inductance depending on their length relative to the length of the waves in the line.

An important design criteria for many components of embodiments is the uniformly small bandwidth of the energy and electronic circuits. Conversion of black body radiation to electricity is generally viewed as a wide bandwidth problem because the Boltzman curve extends from single digit THz into the hundreds of THz. Reducing this bandwidth according to embodiments begins with the use of a metamaterial to form a plasmon resonance. This plasmon resonance is designed in combination with the rectenna antenna's slightly greater bandwidth to maximize energy transfer into the rectenna. The antenna then supplies a relatively narrow band signal to the compensation circuit elements. This is important since the compensation circuits only work well in resonant bands. These bands are designed to match the incoming band from the rectenna's antenna. In this way elements of the system work together for efficient harvesting.

In an embodiment, the resonant elements of the collector/converter devices comprise electrically conductive material coupled with a transfer structure (diode) to convert electrical energy stimulated in the resonant element to direct current. Exemplary such resonant elements are described in more detail in U.S. Pat. No. 7,792,644, filed Nov. 13, 2007, entitled, “Methods, computer readable media, and graphical user interfaces for analysis of frequency selective surfaces” and U.S. Pat. No. 6,534,784, filed May 21, 2001, entitled, “Metal-oxide electron tunneling device for solar energy conversion”, and U.S. patent application Ser. No. 11/939,342, filed Nov. 13, 2007, entitled, “Structures, Systems and Methods for Harvesting Energy from Electromagnetic Radiation” (U.S. Patent Pub. No. 2010/0284086), and Ser. No. 11/471223, filed Jun. 20, 2006, entitled, “Systems and methods for roll-to-roll patterning” (U.S. Patent App. Pub. No. 2006/0283539) each of which is incorporated by reference herein in its entirety.

Additional features and embodiments of the present invention will be evident in view of the following drawings and detailed description of the invention.

### BRIEF DESCRIPTION OF THE DRAWINGS

FIG. 1 is a schematic diagram of a system for harvesting energy from a heat source and supplying the generated electricity to a load.

FIG. 2 is an orthographic projection of a metamaterial and coupled rectenna with associated compensation circuitry according to an embodiment of the present invention.

FIG. 3 is a cross-section view of an exemplary metamaterial structure illustrating a 3D confinement of plasmonic energy and resulting concentration of e-field at a region where the antenna is positioned according to an embodiment of the present invention.

FIG. 4 is a cross section of metamaterial coupled rectenna showing an exemplary antenna, metamaterial substrate, and that illustrates an engineered placement of rectenna between a lower metamaterial and a reflector structure according to an embodiment of the present invention.

FIG. 5 is a schematic illustration of a compensation structure arranged at the feed point of an antenna element for the purpose of performing impedance matching between antenna and diode.

FIG. 6 is a cutaway drawing that illustrates an embodiment of using microstrip transmission lines with engineered geometry and permittivity of surrounding materials to achieve THz transportation of energy and tuning of impedance.

FIG. 7 is a schematic diagram of an equivalent Rectenna circuit illustrating that the nonlinear reactance of the antenna and nonlinear reactance of the diode can be compensated for with an impedance matching network and a resistive load.

FIG. 8 illustrates a top-view of an antenna structure and antenna geometric parameters that can be tailored for maximum plasmonic energy transfer to the antenna feed point and to the attached transmission line structure according to an embodiment of the present invention.

FIG. 9 illustrates a further embodiment to tailor the compensation circuitry through tapping the antenna off-center and nonsymmetrical between arms of the bowtie resulting in variance in the fringing fields and alteration of impedance.

FIGS. 10A, 10B, and 10C illustrate several transmission line circuit elements to compensate for the high parasitic capacitance of THz diodes using elements of transmission line according to embodiments.

FIG. 10D further illustrates compensation of diode capacitance when the diode is directly embedded in the feed point of the antenna.

FIG. 11 is a technical illustration of single pole compensation structures perpendicular to the feed point of an antenna, with the differential transmission line elements in a balanced mode of operation.

FIG. 12 is a technical illustration of single pole compensation structures perpendicular to the feed point of an antenna, with the differential transmission line elements in an unbalanced mode of operation.

FIG. 12A is a chart containing stub lengths and distances for a compensation circuit as well as measured responses according to an embodiment of the present invention designed for 1 THz.

FIG. 13A illustrates in cross section an exemplary MIIM structure for diode according to an embodiment.

FIG. 13B is a graph illustrating a responsivity vs. voltage curve of a MIIM diode fabricated according to an embodiment of the present invention.

FIG. 14 is a cutaway drawing illustrating one embodiment of connecting a metal-insulator-insulator-diode between a differential transmission line in a method that reduces parasitic reactance of the diode.

FIG. 15 is illustrates integration of a THz rectifying diode to a differential transmission line having a broad-band transmission line compensation structure using multiple stubs to achieve a multi-pole resonant response and that also serves to boost the voltage to the diode according to an embodiment of the present invention.

FIG. 16 illustrates a broad-band transmission line compensation structure that implements multi-stage stepped impedance elements to act as an impedance transformer between the antenna and diode according to another embodiment of the present invention.

FIG. 17 illustrates a broad-band transmission line compensation structure that implements ladder topology stepped impedance transforms to replicate lumped element L-C behavior according to another embodiment of the present invention.

FIG. 18 illustrates a fractal bowtie antenna that provides means to engineer the electron/plasmonic wave conduction path and the relative refractive index of the antenna according to an embodiment.

FIG. 19 is an orthographic projection illustrating use of a tapered transmission line to guide and focus surface waves to a nanofocus in the region of the diode.

FIG. 20 illustrates a cross sectional diagram of a metamaterial with a metamaterial coupled rectenna that comprises a rectifying antenna (rectenna) with a near field metal reflector over a hole in a metamaterial according to an embodiment.

FIG. 21 illustrates a cross sectional diagram of a metamaterial with a metamaterial coupled rectenna that comprises a rectifying antenna (rectenna) with a far field DBR reflector over a hole in a metamaterial according to an embodiment.

FIG. 22A illustrates the electric field magnitude (V/m) of SP modes generated using far-field excitation of a metamaterial (patterned Copper (Cu)) surface with no reflector.

FIG. 22B illustrates the electric field magnitude (V/m) of SP modes generated using far-field excitation of a metamaterial (patterned Cu) surface that are significantly confined in the vertical direction using a reflector.

FIG. 23 illustrates a cross section of 3D metamaterial with a metamaterial coupled rectenna.

FIG. 24A illustrates a rectenna during fabrication to show vias etched or ablated through the substrate.

FIG. 24B illustrates a rectenna during fabrication after metal deposition of the eventual backside contacts by filling the vias with a conductive material.

FIG. 24C illustrates a rectenna during fabrication illustrating after formation of distinct interconnects on the backside of the substrate.

FIG. 24D illustrates a rectenna 208 with a reflector 402 that also serves as a local interconnect, combined with global interconnects on the backside of the substrate (side view).

FIG. 24E illustrates a top down view of a group of 8 rectifying antennas that are locally connected in series by two reflector/local interconnects between the substrate and rectifying antenna, each reflector interconnect connecting either the p-side or n-side of the diodes.

FIG. 25 is a schematic diagram of an equivalent circuit that illustrates a basic conventional rectenna circuit.

FIG. 26 is a schematic diagram of an equivalent circuit that illustrates a basic two-pole resonant structure implemented with discrete components, in accordance with an embodiment of the present invention.

FIG. 27 is a schematic diagram of an equivalent circuit that illustrates a higher order four-pole resonant structure implemented with discrete components according to an embodiment of the present invention.

FIG. 28 is an exemplary voltage vs. current characteristic curve of a typical diode used in a rectenna circuit according to an embodiment of the present invention.

FIG. 29 is a schematic diagram of an equivalent circuit that illustrates a two-pole compensation structure for diode capacitance implemented with discrete components, in accordance with an embodiment of the present invention.

FIG. 30 is a schematic diagram of an equivalent circuit that illustrates a four-pole compensation structure for diode capacitance implemented with discrete components, in accordance with an embodiment of the present invention.

FIG. 31 is a schematic diagram of an equivalent circuit that illustrates a four-pole compensation structure for diode capacitance implemented with discrete components, in accordance with another embodiment of the present invention.

FIG. 32 is a schematic diagram of an equivalent circuit that illustrates a modified four-pole resonant structure implemented with discrete components, in accordance with an embodiment of the present invention.

FIG. 33 is a schematic diagram of an equivalent circuit that illustrates an input impedance boost structure and diode capacitance compensation circuit implemented using transmission line components, in accordance with embodiments of the present invention.

FIG. 34 shows simulated voltage and currents corresponding to a conventional rectenna circuit that is without compensation circuitry described herein.

FIG. 35 shows simulated voltage and currents corresponding with the addition of compensation circuitry according to an embodiment of the present invention.

FIG. 36 illustrates a frequency response curve corresponding to a compensation circuit according to an embodiment of the present invention.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles herein may be applied to other embodiments. Thus, the present invention is not intended to be limited to the embodiments shown but is to be accorded the widest scope consistent with the principles and features described herein.

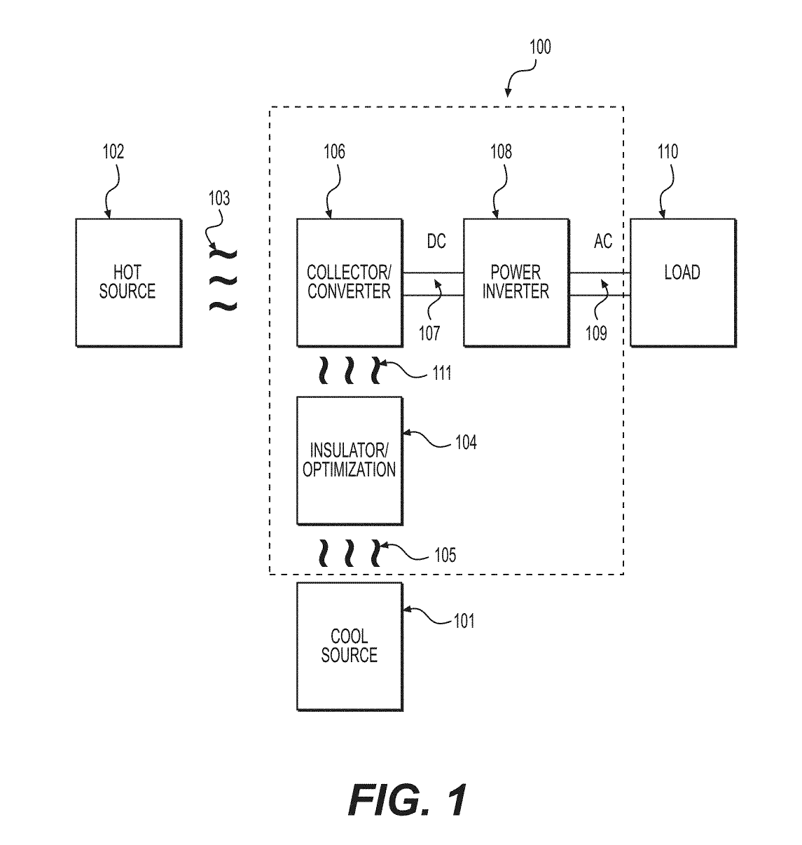

FIG. 1 is a schematic diagram of a system 100 for harvesting energy from a heat source 102 and supplying the generated electricity to a load 110. A collector/converter device 106 collects heat 103 provided by heat source 102 and converts that heat to direct current (DC). In embodiments, the DC is converted to alternating current (AC) by coupling collector/inverter 106 to a power inverter 108 over a bus 107. The generated AC can then be supplied to load 110 over a bus 109. Conversion to AC is optional as some applications may require direct DC.

In an embodiment, an insulator/optimization layer 104 is interposed between cool source 101 and collector/converter device 106. Insulator/optimization layer 104 optimizes heat transfer 111 from heat source 102 to collector/converter 106 to make converting heat generated by heat source 102 to electricity by collector/converter device 106 more efficient. In an embodiment, insulator/optimization layer 104 operates by selectively allowing thermal access 105 to a cool source 101 where needed at converter elements of collector/converter 106 and thermally insulating elsewhere.

In an embodiment, collector/converter 106 comprises a plurality of collector/converter devices, for example, nanoantenna electromagnetic collector (NEC) devices, also called rectennas. Each NEC device comprises a resonant structure that is tuned to heat frequencies or to the surface plasmon resonant frequencies of a paired metamaterial, and generates an electric current in the presence of electromagnetic energy from heat sources. In an embodiment, a transfer structure converts electrical energy stimulated in the resonant elements of the NEC's resonant structure to DC. In an embodiment, the transfer structure is a metal insulator metal (MIM) or a metal-insulator-insulator-metal (MIIM) diode. In an embodiment, collector/converter 106 comprises a film that contains a high density of NEC devices that cover the surface of the film. A film so constructed is referred to as a NEC film.

Additional details concerning NEC devices and metamaterials as described herein can be found in U.S. patent application Ser. No. 14/745,299, filed Jun. 19, 2015 (US 2015-0335962), Ser. No. 14/187,175, filed Feb. 21, 2014 (US 20140126441), Ser. No. 14/108,138, filed Dec. 16, 2013 (US 20140172374), and Ser. No. 13/708,481, filed Dec. 7, 2012 (US 20130146117), each of which is hereby incorporated herein by reference in its entirety.

### 3D Metamaterial Coupled Rectenna

### System Level Description

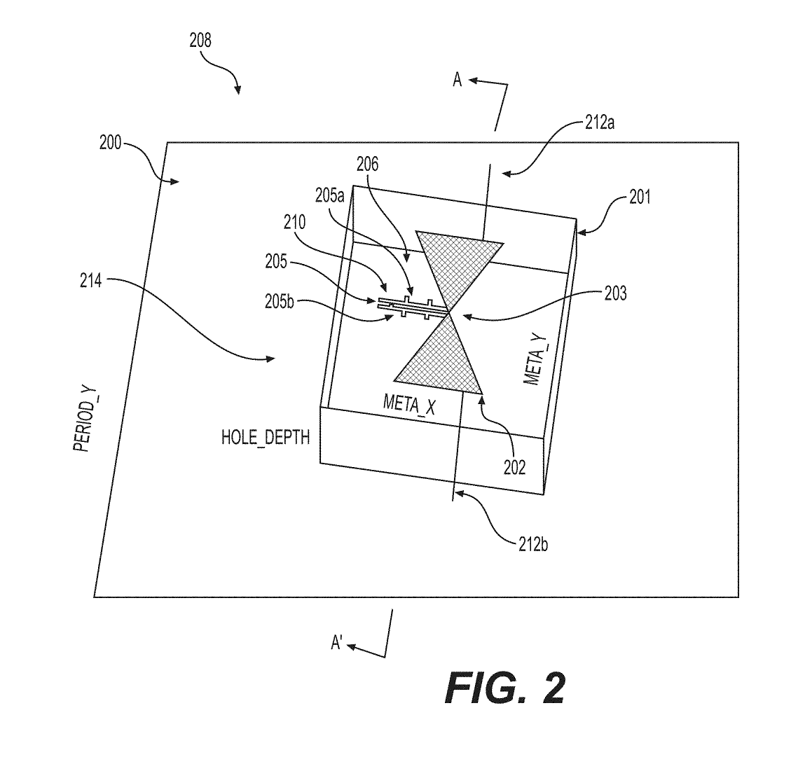

FIG. 2 is an orthographic projection of a metamaterial 200 and coupled rectenna 206 with associated compensation circuitry 205 according to an embodiment of the present invention. Together metamaterial and coupled rectenna 206 are referred to herein as a metamaterial coupled rectenna 208. As illustrated in FIG. 2, metamaterial coupled antenna 208 comprises a rectenna 206 positioned above a metamaterial 200. Preferably metamaterial 200 is a 3D metamaterial characterized by a pattern of features on its surface 210. For example, in embodiments, the features can be holes or poles. As illustrated in FIG. 2, for example, 3D metamaterial 200 is designed with sub-wavelength holes/features 201. Holes 201 induce and channel plasmonic waves on the surface of metamaterial 200 as well as concentrate electromagnetic e-fields at a specific bandwidth and frequencies of operation. A rectenna 206 includes an antenna element 202. In an embodiment, rectenna is positioned above hole 201.

Metamaterial and coupled rectenna 206 also includes transmission line 205 that comprises transmission line leads 205a and 205b. Transmission line 205 couples a voltage signal generated by antenna element 202 to a diode 210. Diode 210 operates to rectify the voltage signal to generate a DC current. Together antenna element 202 and diode 210 comprise rectenna 206.

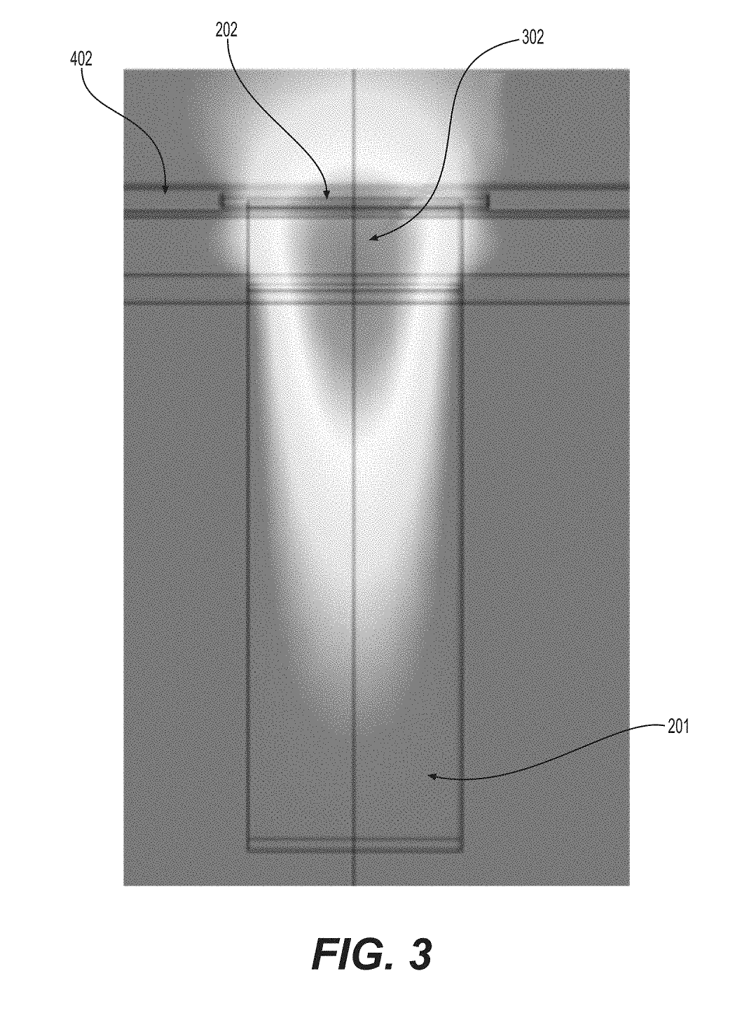

FIG. 3 is a cross-section view of an exemplary metamaterial structure illustrating a 3D confinement of plasmonic energy and resulting concentration of e-field 302 at a region where antenna element 202 is positioned. The concentration of energy is a function of the geometry of the metamaterial features and relative positioning of antenna element 202 and upper reflector 402 (described below). Upper reflector 402 has a gap above the rectenna in this embodiment but other embodiments may use a contiguous layer or near contiguous reflector layer. Rectenna element 206 may also be positioned at differing positions between reflector layer 402 and the metamaterial As illustrated in FIG. 3, in operation, antenna element 202 is positioned in an e-field 302 at the point of maximum intensity during operation of an embodiment. In an embodiment, antenna element 202 is designed with a complementary bandwidth and operating frequency for optimal coupling of energy from the metamaterial. For example, antenna element 202 is designed to match the small bandwidth of the surface plasmons and tuned to the surface plasmon resonant frequency.

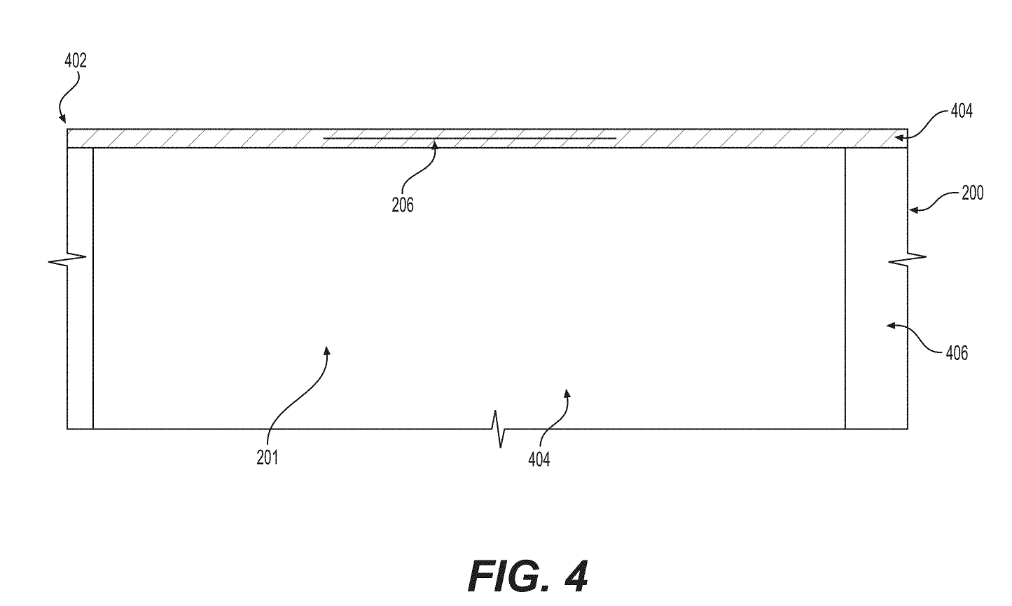

FIG. 4 is a cross section of metamaterial coupled rectenna 208 in FIG. 2 taken at A-A′ showing an exemplary antenna, metamaterial substrate, and that illustrates an engineered placement of rectenna 206 between lower metamaterial 200 and reflector structure 402 according to an embodiment of the present invention. FIG. 4 illustrates rectenna 206 (including antenna element 202) suspended above metamaterial hole 201 and below a top metamaterial reflector 402. During fabrication of an embodiment, positioning of the antenna element in the Z direction is controlled by deposition of standoff layer(s) 404. Standoff layer(s) 404 act as an electrical and thermal insulator while providing low loss optical transmission that allows radiation through standoff layer(s) 404. A non-exhaustive list of materials having these properties include SiO₂, SU8, aerogels. In an embodiment, standoff layer(s) 404 are a vacuum with the exception of standoff material above the rectenna 206 in order to hold it in proper location.

Referring back to FIG. 2, a transmission line 205 extends from a feed point 203 of antenna element 202. In an embodiment, transmission line 205 comprises transmission line leads 205a and 205b. Transmission line leads 205a and 205b act as a wave guide to connect to a rectifier diode 210. The combination of an antenna element 202 with a diode 210 is termed a rectenna, such as rectenna 206. In an embodiment, transmission line elements 205a and 205b are designed to perform impedance matching of antenna element 202 with diode 210. Rectified DC is taken off the rectenna 206 antenna element 202 by leads 222a and 222b and passed to a bus structure (not shown). In an embodiment, the bus structure also interconnects multiple rectenna elements together.

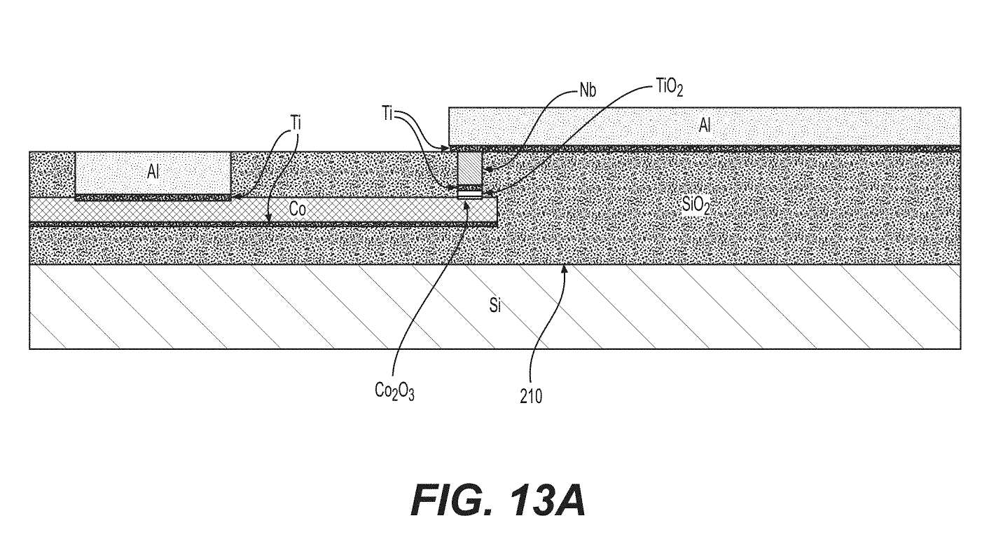

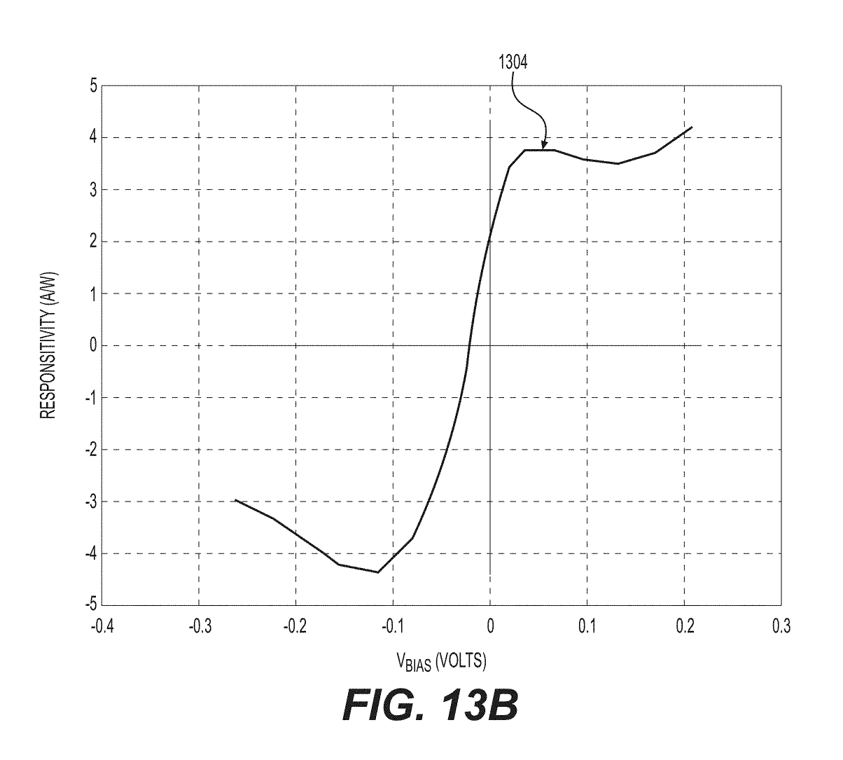

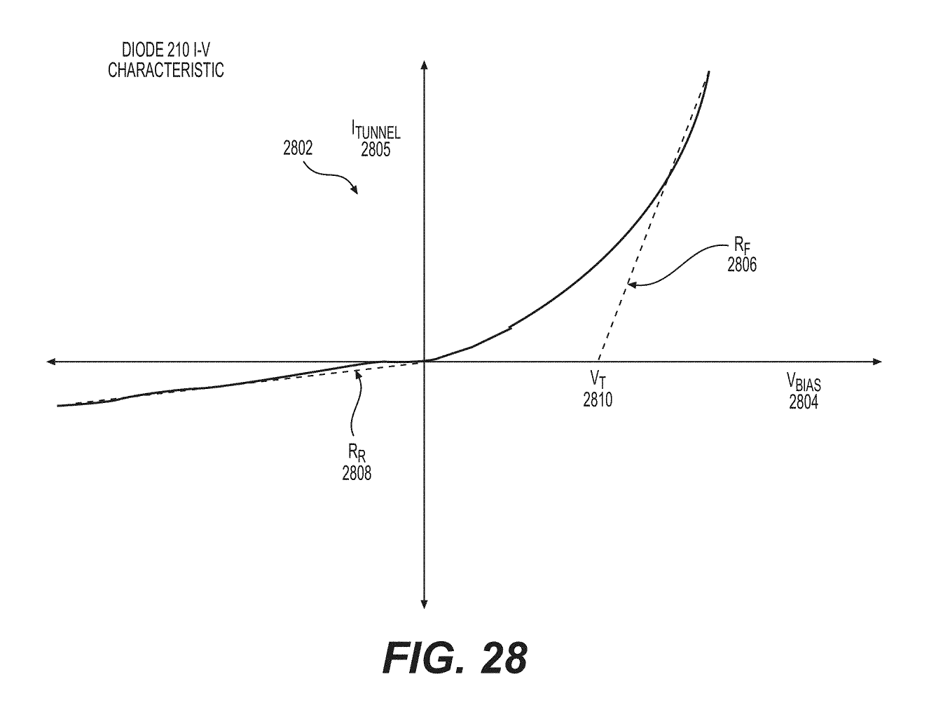

In an embodiment, antenna element 202 is designed to absorb plasmonic radiation at terahertz (THz) frequencies radiated from metamaterial 200 in the presence of heat. In operation, antenna element 202 generates evanescent surface waves that propagate to the antenna feed point 203 and are channeled through impedance matching transmission circuit 205 to diode 210. In embodiment, diode 210 is a metal-insulator-metal (MIM) diode. In embodiment, diode 210 is a metal-insulator-insulator-metal (MIIM) diode. Such a MIIM diode for use in embodiments is described in more detail with respect to FIGS. 13A and 28. In an embodiment, impedance matching transmission line 205 comprises transmission line leads 205a and 205b.

In an embodiment, 3D metamaterial 200 employs a metal-insulator-metal structure for field confinement and wave guidance of a generated surface plasmons. The structure has metallic boundaries that introduce reflections to constructively interfere, channel, and localize the generated surface plasmon. Referring back to FIG. 4, metamaterial coupled rectenna 208 has a multi-layer structure. In operation, a heat source is applied to an underside of 404 (layer #1) via of metamaterial coupled rectenna 208. In an embodiment, metamaterial periodic hole features 201 are designed in the surface of the metamaterial 200 with a geometry to tune metamaterial 200 for plasmonic resonance at the frequency of THz energy harvesting. For instance, at 5 THz the spacing between holes could be in the range of 45 um. Hole could be near 15 um but dimensions may vary considerably depending on materials, effects of rectenna 206, reflector 402 distance from the metamaterial, etc. The depth of the hole 201 is optimized to push more light out and localize it onto antenna element 202 of rectenna 206. Antenna element 502 therefore acts as a photon collector.

To fabricate metamaterial 200, a periodic pattern of holes 201 are drilled into a material 200 (generally a metal). The spacing or periodicity of the hole is designed to sustain a surface plasmonic wave and to couple energy to each antennal element 202. In alternate embodiments, the hole pattern is aperiodic and/or holes are of varying sizes. In an embodiment, arrays of rectennas 206 are implemented. Referring back to FIG. 2, a single unit cell of a metamaterial rectenna 208 is illustrated. In an embodiment, this unit cell is replicated to create large area arrays of energy harvesting structures.

Metamaterial coupled rectenna 208 further comprises an upper metamaterial reflector structure 402. In an embodiment, substrate 406 and metamaterial reflector structure 402 are separated with inert spacer material such as standoff layer(s) 404. The inert spacer material provides support and positioning of rectenna 206. Variations on this design are shown in FIG. 4 whereby the positioning of the rectenna and surrounding material are optimized to provide cooling of the rectenna and insulation around the rectenna to maximize efficiency of the system. Additional details concerning thermal management for embodiments is described in U.S. patent application Ser. No. 14/187,175, filed Feb. 21, 2014, entitled, “Structures, System, and Method for Converting Electromagnetic Radiation to Electrical Energy,” U.S. Pat. Pub. No. 2016/0126441, which is hereby incorporated herein by reference in its entirety.

### System Level Integration of Multi-Stage Compensation

### Impedance Match and V_{boost}

In an embodiment, antenna element 202 of rectenna 206 is a bowtie antenna with an antenna feed point 203. Attached to antenna feed point 203 is a coplanar differential transmission line 205. Differential transmission line 205 is comprised of differential transmission line leads 205a and 205b. Differential transmission line leads 205a and 205b act as a dual microstrip transmission line structure to integrate diode 210 into rectenna 206 for the purpose of rectification of THz signals received by the antenna element 202. Diode 210 can be a MIM diode, MIIM diode, or any other diode that can rectify signals in the THz frequency range. As described in further detail below, transmission line 205 is designed to implement an impedance transform between antenna element 202 and diode 210 to achieve maximum power transfer. Transmission line 205 also transforms antenna current into a diode voltage boost to ensure the diode is biased into a nonlinear operating mode.

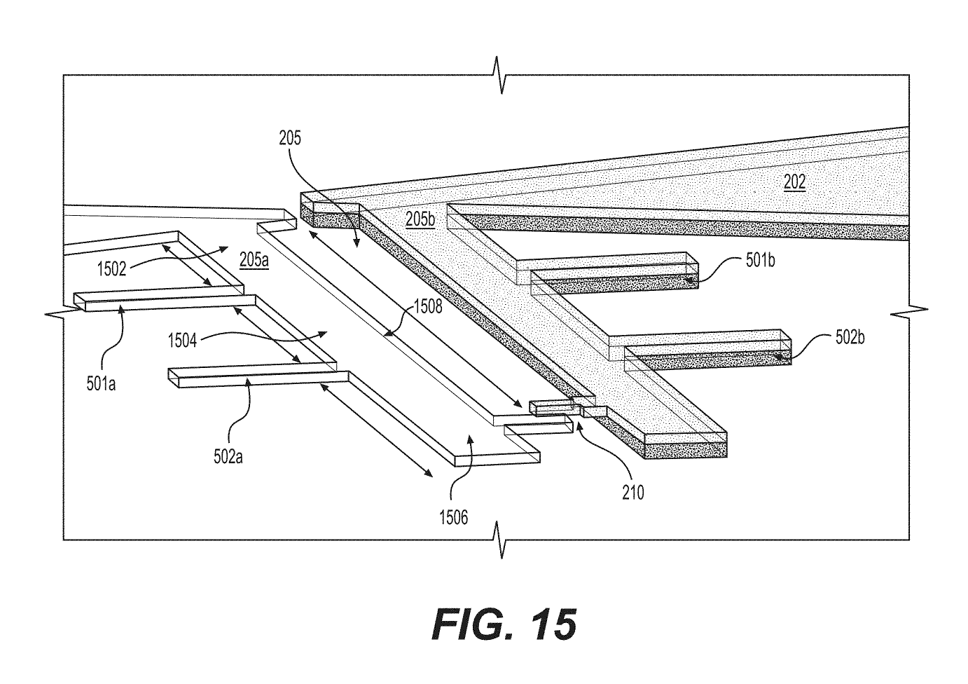

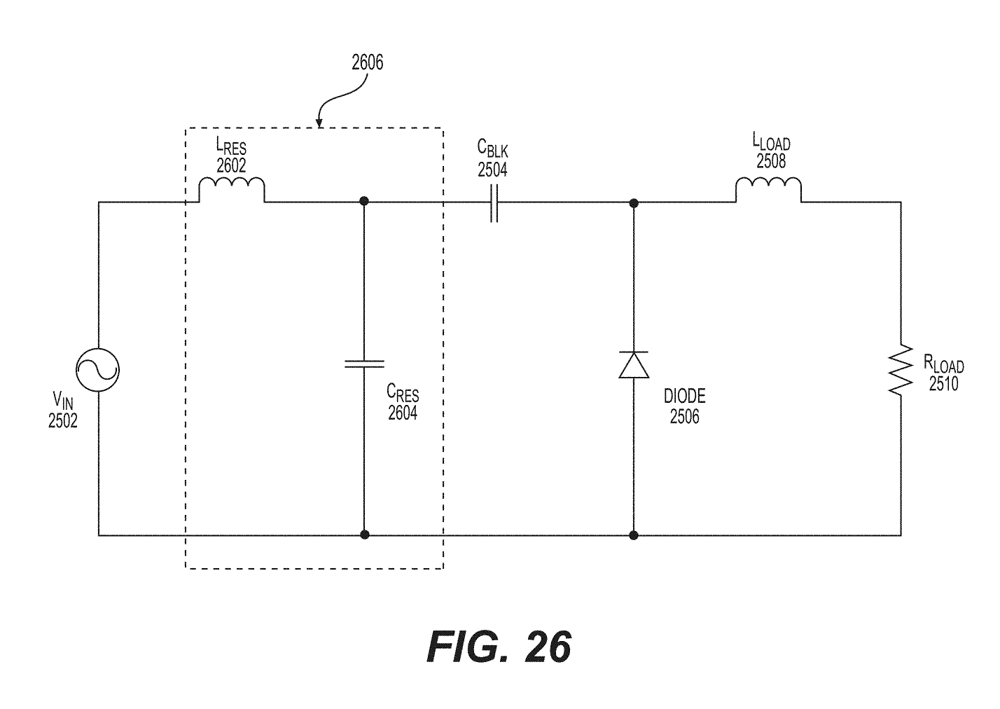

In an embodiment, the impedance matching circuit provided by transmission line 205 operates to match the complex impedance of antenna element 202 to the complex impedance of diode 210, for example a high resistance MIM or MIIM diode. An exemplary such high resistance MIIM diode 210 is illustrated in FIGS. 15A and 15B. The impedance matching network is based on lumped passive elements (e.g., inductors and capacitors) as shown, for example, in the equivalent circuit schematic diagrams illustrated in FIGS. 26-27 and 29-33 as explained in more detail below. In an embodiment, rather than use discrete component capacitor and inductors, the impedance matching network in is implemented using high frequency distributed elements (e.g., transmission lines and stubs) that act as discrete capacitor and inductor elements at high, e.g. THz, frequencies.

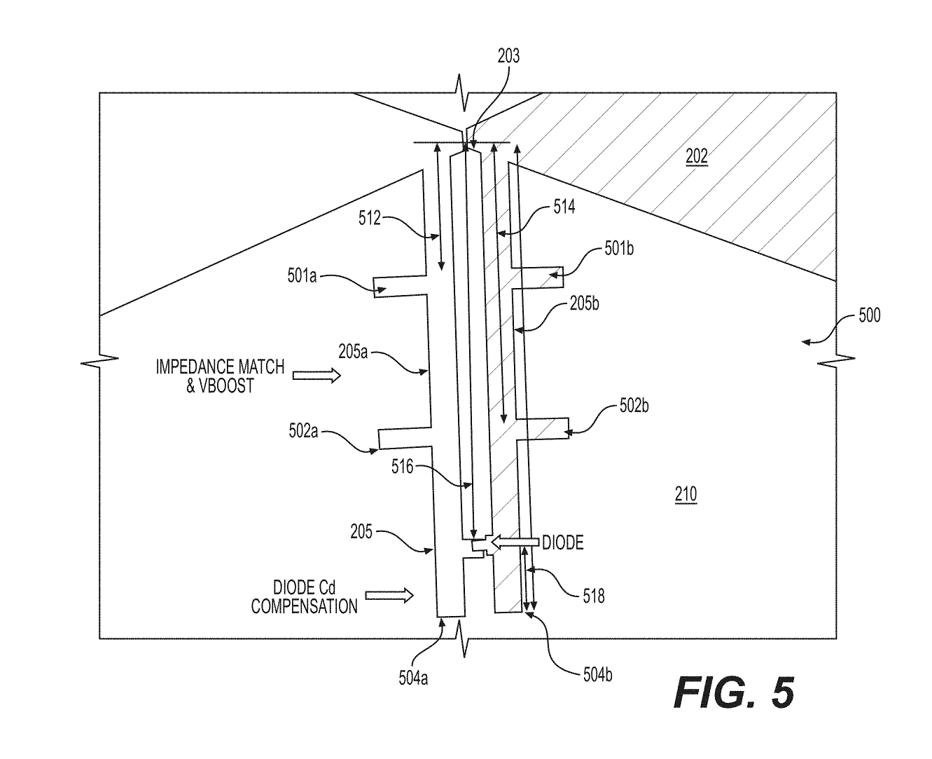

FIG. 5 is a schematic illustration of a compensation structure 500 arranged at feed point 203 of antenna element 202 for the purpose of performing impedance matching and voltage boost between antenna and diode. As shown in FIG. 5, according to an embodiment, compensation structure 500 comprises transmission line 205 that comprises structures comprised of differential, co-planar transmission line elements or leads 205a and 205b, and stubs 501a-d. Compensation structure 500 also boosts the voltage to the diode and introduces inductive reactance to cancel out diode capacitance. In an embodiment, and at a representative frequency of 1 THz, the compensation structure illustrate in FIG. 5 is a quarter wavelength transformer 500 implemented via transmission line 205 according to an embodiment. Quarter wavelength transformer 500 includes open stubs 501a, 501b, 502a, and 502b. In an embodiment, stubs 501a, 501b, 502a, and 502b are interconnected to perform quarter-wave transformers for impedance matching of antenna to diode. Stubs 501a and 501b are positioned at a distance 512 from feed point 203. In an embodiment, distance 512 is 4 μm. Stubs 502a and 502b are positioned at a distance 514 from feed point 203. In an embodiment, distance 514 is 9 μm. Diode 210 is placed at a distance 516 from feed point 203. In an embodiment, distance 516 is 12 μm.

As described in more detail below, at high, such as THz frequencies, open stubs 501a, 501b, 502a, and 502b implement L-C network behavior that performs impedance matching between antenna element 202 and diode 210, as well as provides a voltage boost to raise the signal to be converted by diode 210 closer to, if not in the optimal operating range of diode 210. The impedance transformer is a function of the spacing between stubs 501a and 501b and between stubs 502a and 502b, as well as their respective lengths. Diode 210 also introduces parasitic capacitance from the metal-insulator-metal interface. In an embodiment, diode 210 is placed a distance 518 to compensate for this parasitic capacitance by transmission line segments 504a and 504b. In an embodiment, distance 518 is 4 μm from the end of a transmission line 205.

The output of antenna element 202 is input to a differential impedance matching network, such a quarter wavelength transformer 500, through feed point 503. The differential impedance matching network comprises a transmission line 205. In one embodiment transmission line 205 is implemented using differential micro strips 205a and 205b.

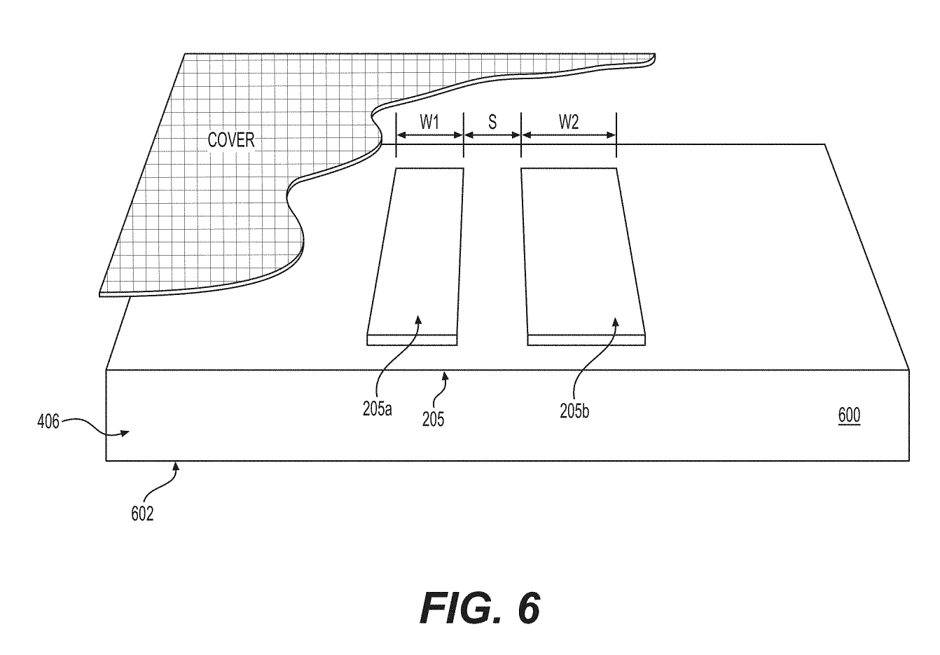

FIG. 6 is a cutaway drawing that illustrates an embodiment of using microstrip transmission lines with engineered geometry and permittivity of surrounding materials to achieve THz transportation of energy and tuning of impedance. FIG. 6 also illustrates that the phase of the EM radiation can be tailored using an embodiment. As illustrated in FIG. 6, in an embodiment, microstrip transmission lines 205a and 205b comprise a conductive strip of width “W1” and “W2” and thickness “t”. Widths W1 and W2 are preferably the same, but need not be. Transmission line leads 205a and 205b are separated by a dielectric layer (a.k.a. the “substrate”) of thickness “H” from a wider ground plane 602. Microstrip transmission lines 205a and 205b channel specific wavelengths of electric field lines. In theory, half of the EM field lines are contained within the substrate below and the other half within the material above. Thus, the effective permittivity (J_{eff}) is taken to be the average of the two. In operation, the transport of energy can be tuned by selecting specific materials with different permittivity. Other variable dimensions that can be adjusted are: signal (S), gap widths (w), substrate height (h) and substrate permittivity (εᵣ). Decreasing “S” width increases characteristic impedance. Combinations of all parameters control antenna radiation coupling efficiency (accepted power), real and imagery impedance, and resonance.

The baseline design selects transmission lines with a specific electrical length (or phase length). In an embodiment, this length is in terms of the phase shift introduced by transmission over that conductor at some frequency. The number of wavelengths, or phase, involved in a wave's transit over a segment of transmission line is tailored via repetitive simulations whose results are plotted and compared to show best results. The electrical length of a transmission line is primarily dependent on two factors: 1) the velocity factor of the line and 2) the frequency of operation.

### Tuning Velocity of Propagation.

The propagation delay is the length of time it takes for a signal to travel down a conductor to its destination. In a transmission line, a signal travels at a rate controlled by the effective capacitance and inductance per unit of length of the transmission line. Stubs and shorts alter the reactance. The velocity of propagation, that is, the speed at which a wavefront of an electromagnetic signal passes through the medium relative to the speed of light, is tuned by tailoring the metal conductivity of transmission line leads 205a and 205b and the permittivity of the standoff layer insulator 404 as shown in FIG. 4. Materials are selected to optimize simulation results.

### Transmission Line Stubs

A primary building block of compensation circuits according to embodiments are stubs 501a-b and 502a-b connected to a transmission line leads 505a and 505b. A stub is a length of transmission line that is connected at one end only. It is terminated in a short (or open) circuit. The length of the stub is chosen to produce the desired impedance. The input impedance of the stub is purely reactive, either capacitive or inductive. Stubs work by means of standing waves along their length. Their reactive properties are determined by their physical length in relation to the wavelength of the standing EM wave along their length. Thus, stubs may function as capacitors or inductors. Full wave finite element analysis of the metamaterial coupled rectenna structure 208 is performed using parametric optimization of geometry of compensation structure and complex impedance of antenna and diode reactance. The circuit is physically tuned for maximum power transfer from antenna element 202 to diode 210, and for optimum impedance matching.

### Rectenna Circuit

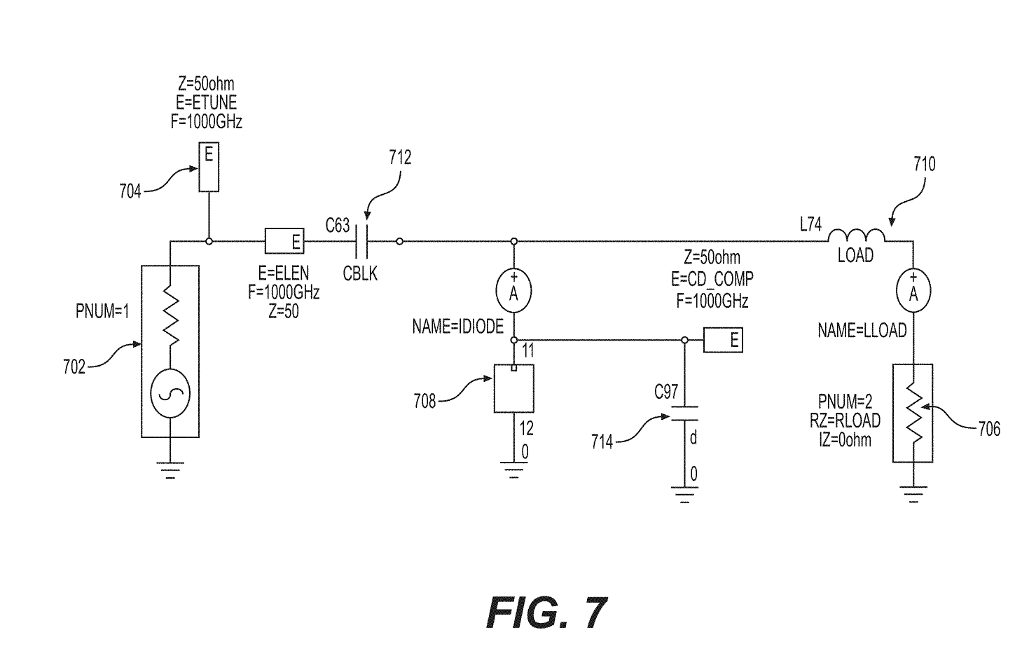

FIG. 7 is a schematic diagram of an equivalent rectenna circuit illustrating that the nonlinear reactance of the antenna and nonlinear reactance of the diode can be compensated for with an impedance matching network and a resistive load. As illustrated by the equivalent circuit in FIG. 7, rectenna 206 (represented by voltage source and source resistance combination 702) and impedance matching network 205 (represented by differential impedance matching network interface 704) are loaded by two elements in parallel, namely (1) a load resistor 706 connected across the differential impedance matching network interface 704; and (2) a rectifying element diode 708 (such as diode 210) connected in a parallel configuration as shown in FIG. 7. The compensation circuitry is further tuned to include reactance of external load components 710, 706. In the circuit illustrated in FIG. 7, capacitor 712 is an inherent capacitance in a rectenna circuit between the antenna and diode. Capacitor 714 is the capacitance of the diode 708 in this equivalent circuit.

### Antenna Compensation

In an exemplary embodiment, antenna element 202 of rectenna 206 is configured to have a center frequency of operation of 30 THz. Such an antenna corresponds to a wavelength of approximately 10 μm. At THz frequencies the propagation of electrons in antenna element 202 is primarily by surface plane waves. Material properties and the geometry of the conductive antenna is critical to reduce losses. Numerous antenna topologies are suitable for use in embodiments of the present invention. A preferred embodiment uses a bowtie antenna, whose size is approximately 3 μm, which exhibits optimal absorption of energy in this frequency band. In an embodiment, 3 um refers to the length end-to-end of the bow tie structure. A bow tie has an outer edge length and an angle. These are specifics and matter more to the bandwidth of the antenna. The end-to-end length places the antenna in the radiation spectrum. The antenna material needs to be highly conductive in the THz region. Au and Ag are good materials for this purpose.

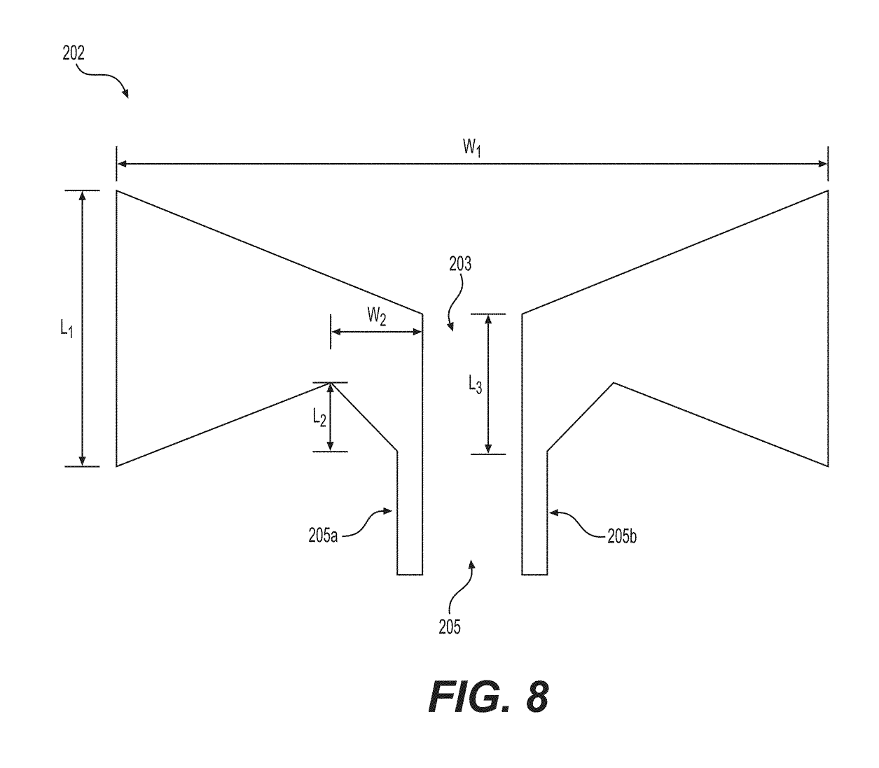

FIG. 8 illustrates a top-view of an antenna element 202 structure and antenna geometric parameters that can be tailored for maximum plasmonic energy transfer to the antenna feed point 203 and to the attached transmission line structure according to an embodiment of the present invention. In the embodiment illustrated in FIG. 8 antenna element 202 is a bowtie type antenna. A bowtie type antenna element 202 provides a tunable bandwidth and impedance as a function of flair and angles of the antenna. Plasmonic current waves propagate through the antenna structure. The preferred mode of propagation is line of sight. To optimize channeling of the EM waves into the transmission line structure the antenna is modified with a tapered feed 203. This reduces abrupt boundary changes that cause reflected waves.

Reduction of reflections from antenna element 202 to the differential impedance match structure, such as transmission line 205, is achieved by choosing L₂, L₃, W₂, to control the bowtie flair angle and the tapering of the transmission line as shown in FIG. 8. As L₃ decreases the bowtie flare angle increases, causing the resonance frequency to shift higher and the bandwidth to increase.

The parameters W₂, L₁ and L₂ control the level of the return loss at the main resonance frequency. Effects of the adjustment of these parameters are discovered through iterative simulations that vary each parameter in order to maximize efficiency.

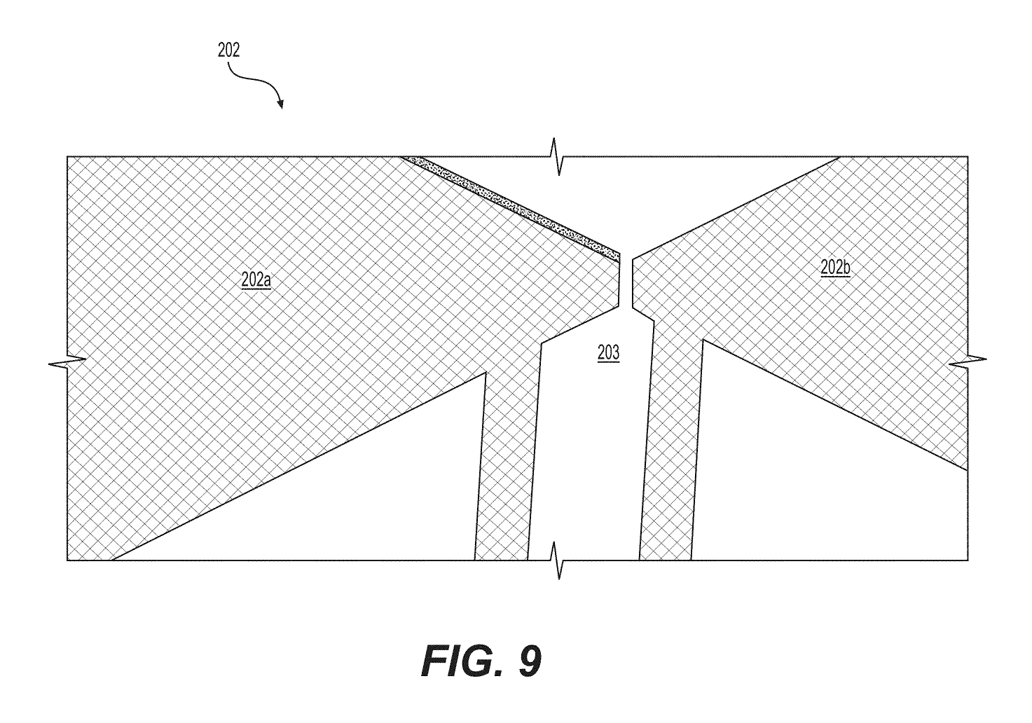

FIG. 9 illustrates tailoring of the compensation circuitry by tapping antenna element 202 off-center and nonsymmetrical between arms of the bowtie components 202a and 202b of a bowtie-type antenna element 202 according to an embodiment. This results in variance in the fringing fields and alteration of impedance. Using an asymmetrical feedline in this manner provides another control mechanism for tuning impedance match circuitry. Iterative simulation provides optimal placement.

### Diode Cd Compensation

MIM and MIIM structures, by their physical geometry, introduce high parasitic capacitance. This parasitic capacitance is parallel to the nonlinear rectification, and may thus short-circuit the rectification if it exhibits enough impedance. The high terahertz frequency causes parasitic capacitance to act as a low impedance load and/or short. Embodiments of the present invention include novel methods to null out such parasitic diode capacitance.

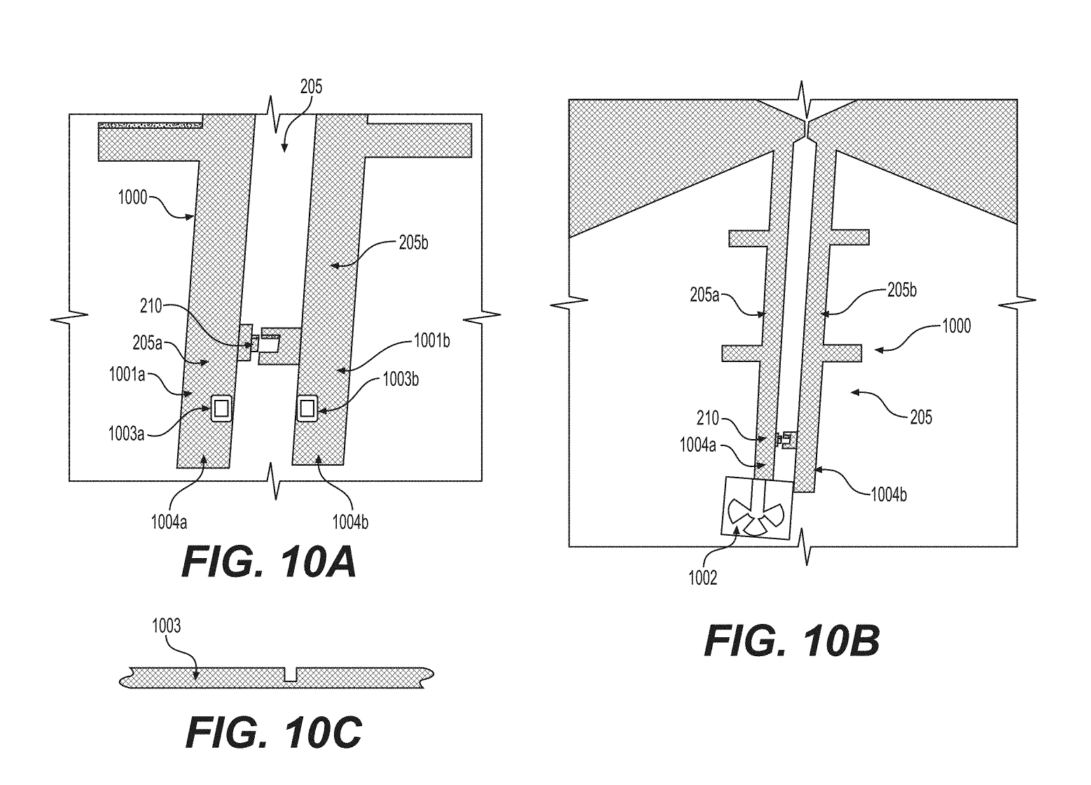

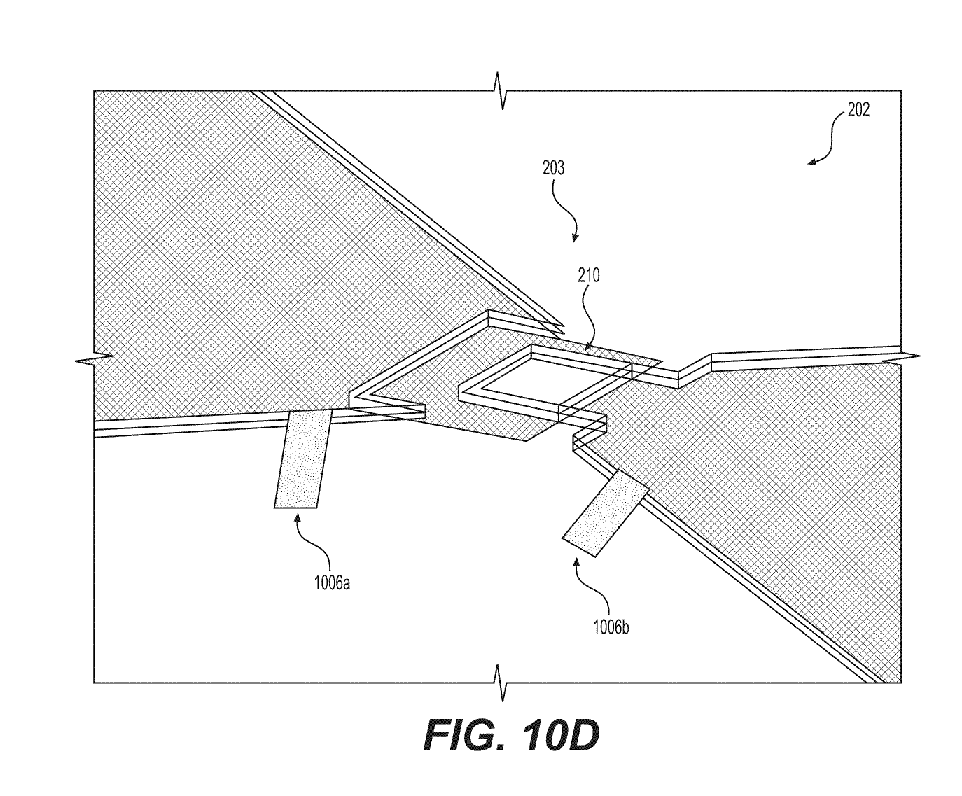

FIGS. 10A, 10B, and 10C illustrate several transmission line circuit elements to compensate for the high parasitic capacitance of THz diodes using elements of transmission line 205 according to embodiments. As shown in FIG. 10A, impedance match structure 1000 includes a transmission line 505 as described above. Impedance match structure 1000 is configured and shaped using distributed design techniques such that a first distributed reactance is generated by transmission line 205 that at least partially cancels out a second distributed reactance inherent in the MIIM structure. The distributed capacitance and inductance of the MIIM structure resonate thus canceling themselves out leaving only the resistive portion.

In the embodiments shown in FIGS. 10A and 10B, diode 210 is configured as a MIIM diode. An impedance matching structure, transmission line 205, comprises transmission leads 205a and 205b. Primary compensation of the diode capacitance is achieved through stubs 1004a and 1004b that extend beyond the diode interface. This single stage compensation provides high Q factor selectively thereby nulling the diode capacitance. In an embodiment, two stage compensation is achieved by using a use of transverse half-slits 1003a and 1003b across the diode compensation stub. FIG. 10C illustrates such an exemplary transverse half-slit 1003 that can be used for transverse half-slits 1003a or 1003b. Transverse half-slits 1003a and 1003b further induce an inductive element, with associated inductive reactance. As such, they assist in cancellation of the diode's capacitive reactance over a wider range of diode capacitance. In an embodiment, only one of transverse half-slits 1003a or 1003b is used. In an embodiment, transverse half-slits 1003a and 1003b have differing geometries. In an embodiment, transverse half-slits are on the order of 1 μm×for a 1 THz device.

The inherent capacitance of the diode 106 MIIM sandwich can also be reduced by implementation of a inductive stub spiral or flair 1002 in close proximity to the bottom metal plate which make up the MIM/MIIM structure as shown in FIG. 10B. Even greater bandwidth of reactance cancellation can be achieved through the use of radial or butterfly cloverleaf stubs 1002.

FIG. 10D further illustrates compensation of diode 210 capacitance when diode 210 is directly embedded in the feed point of antenna element 202. Antenna element 202 is modified with inductive stubs 1006a and 1006b in a region near feed point 203 to cancel diode 210 capacitance. Bowtie antenna with single stage compensation

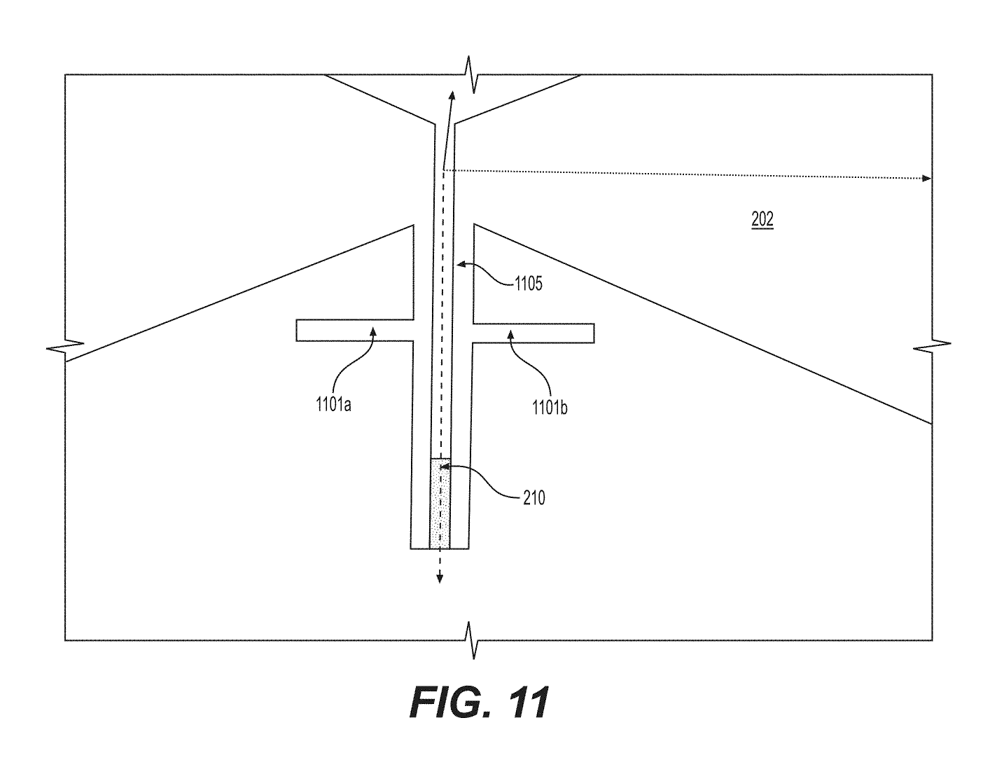

FIG. 11 illustrates an exemplary bowtie antenna element 202 coupled to a transmission line 1105 configured as a single-pole compensation structure perpendicular to feed point 203 that provides balanced compensation to diode 210 using open-circuit stubs 1101a and 1101b perpendicular to main transmission line 1105. Open circuit stubs 1101a and 1101b behave as a series L-C resonator also known as a tank circuit. As such they introduce a lowpass filter response, the impedance of which is determined primarily by the length of stubs 1101a and 1101b. In an embodiment, the distributed transmission line structure is tuned to reflect a small-signal impedance that is the complex conjugate match of the antenna impedance. This configuration results in a high quality factor (high Q) with narrow, selective bandwidth operation. This is desirable for applications that require frequency selectivity such as detectors for spectroscopy or for coupling to restricted bandwidth energy harvesting devices, such as metamaterial or spectrum tuning layer devices.

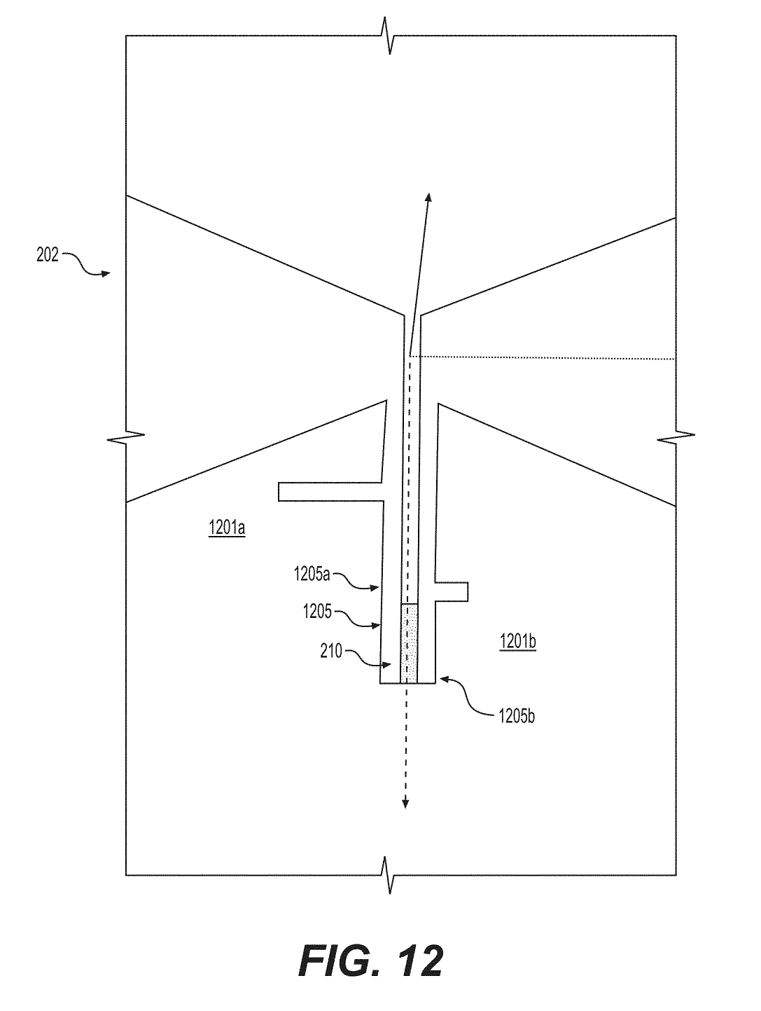

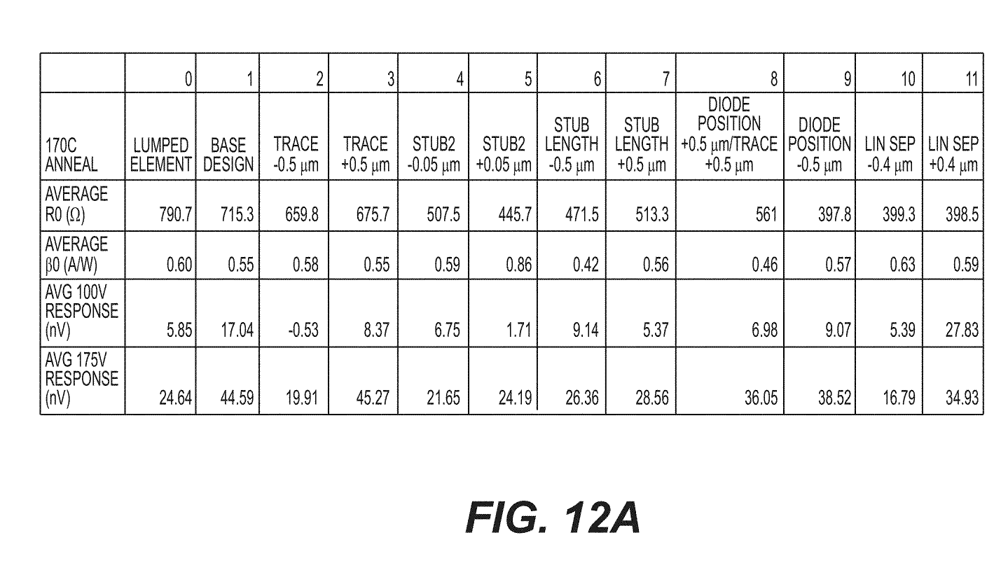

FIG. 12 illustrates an exemplary bowtie antenna element 202 is coupled to a transmission line 1205 configured as a single-pole compensation structure perpendicular to feed point 203 that provides unbalanced compensation to diode 210 using open-circuit stubs 1201a and 1201b perpendicular to main transmission line 1205. Placing adjacent stubs 1201a and 1201b in an asymmetrical configuration results in an unbalanced transmission line 1205. Use of an unbalanced transmission line 1205 may be desirable if the load introduces nonlinear and asymmetrical reactance, as seen by each transmission line lead 1205a and 1205b of differential transmission line 1205. The conduction modes of diode 210 have low forward resistance and high reverse bias resistance. This high frequency modulation distorts the voltage/current phase. Offset placement of compensation stubs can dampen this distortion.

FIG. 12A is a chart containing stub lengths and distances for a compensation circuit as illustrated in FIG. 12 as well as measured responses according to an embodiment of the present invention designed for 1 THz. The base circuit was configured with 400 nm×700 nm; transmission line 1205 with transmission line lead 1205a and 1205b lengths of 14 μm; stub 1201a length of 11.90 μm; stub 1201b length of 3 μm; diode 210 position from feed point 203 of 13 μm; separation between transmission leads 205a and 205b of 3.2 μm. A modified configuration used a stub 1201a length of Transmission line lead 1205a and 1205b lengths of approximately 15 um; width 3.5 um; stub length 1201a of 3 um; and stub 1201b length of 6 um; separation between transmission leads 1205a and 1205b of 3.2 um; with the position of diode 210 of 13 um from antenna feed point 203. As can be seen from the chart in FIG. 12A, the base circuit provided approximately a 3 times voltage boost over a rectenna with no boost circuitry, and one of the modified versions delivered approximately a 5 times voltage boost.

### Diode Interface to Differential Transmission Lines

Preferably diode 210 has a high zero bias responsivity and low resistance suitable for converting heat into electricity. MIIM diodes are most suited to convert heat to electricity over other kinds of diodes due to their high frequency (THz) capability. Previously disclosed MIIM diodes may have high zero bias responsivity but with high resistance. Low resistance in the diode enables low RC time constants, which then enables higher efficiency in converting heat to electricity. A MIIM diode 210 according to an embodiment is designed to have high zero-bias responsivity and low resistance.

FIG. 13A illustrates in cross section an exemplary MIIM structure for diode 210 according to an embodiment. In the embodiment illustrated in FIG. 13A, diode 210 comprises two metal layers, for example, aluminum that sandwich insulators titanium oxide (TiO₂) and cobalt oxide (Co₂O₃) on a Silicon substrate. Titanium layers can be used to help with adhesion for various layers. Cobalt (Co) and niobium (Nb) are antenna materials. In practice, they are often coated with aluminum (Al) or gold (Au) for better conductivity. Silicon Oxide (SiO₂) is the oxide of choice to layer in and separate materials during fabrication. Such a MIIM diode operates to rectify the output of the impedance matching circuit.

In an embodiment, a MIIM diode 210 as illustrated in FIG. 13A is fabricated by depositing titanium and cobalt films by evaporation onto a photoresist pattern on a substrate, and then lifting off the photoresist and metal. In an alternative embodiment, the titanium and cobalt films are deposited on the substrate, and then patterned and etched. In an embodiment, the titanium and cobalt films are 50 Å and 500 Å thick, respectively. The patterned films are then exposed to a 30-Watt oxygen plasma at a pressure of 50 mTorr for 20 seconds to form cobalt oxide (C₂O₃) on the surface of the cobalt. The cobalt oxide film is between 20 Å and 200 Å thick. The titanium oxide (TiO₂) film is deposited by reactive sputtering for 3 minutes, using a titanium target, an atmosphere of 3 mTorr of 60% O₂ and 40% Ar, and a power of 60 Watts. In an embodiment, the titanium oxide film is about 40 Å thick. A titanium film of 50 Å thickness is then deposited by evaporation. A niobium (Nb) film of 2000 Å thickness is then deposited by sputtering. Photoresist is then deposited and patterned by standard lithographic techniques and the stack of Co₂O₃/TiO₂/Ti/Nb is then etched to form the MIIM diode 210.

After etching, a passivating film of SiO₂ is deposited by either evaporation, sputtering, or chemical vapor deposition (CVD). Some of the SiO₂ film is removed by chemo mechanical polishing (CMP), exposing the top surface of the Nb film. Another portion of the SiO₂ film is removed by pattern and etch, exposing a portion of the first Co film. A final upper metal is then deposited, patterned, and etched. This upper metal may be 50 Å Ti+2000 Å Al, deposited by sputtering. A cross sectional schematic of the device is shown in FIG. 13A.

In embodiments, MIIM diode 210 can be fabricated using different insulators and metals can be used so long as the resulting MIIM diode can rectify terahertz signals. Similarly, diodes with different structures, such as MIM diodes, may be used in embodiments. As described above, preferably diodes 210 for use in embodiments have high zero bias responsivity and low resistance suitable for converting heat into electricity.

The performance of a MIIM device fabricated as described above is illustrated as shown in FIGS. 28 and FIG. 13B. In an embodiment, MIIM diode 210 diode has a dimension of 0.3 μm×0.3 um. FIG. 28 is a graph of a current vs. voltage measurement (curve 2802) of a MIIM diode 210 fabricated according to an embodiment of the present invention. FIG. 13B is a graph illustrating a responsivity vs. voltage curve 1304 of a MIIM diode 210 fabricated according to an embodiment of the present invention.

As illustrated by curve 1304 in FIG. 13B, at zero bias, the responsivity of this MIIM diode 106 is 2.16 Amps/Watt. The resistance of this diode was 17,980 ohms (approximately 18 kΩ). In contrast, published reports of conventional MIIM diodes with high (>1 A/Watt) responsivity have coincided with equivalent resistances in the MΩ or GΩ range, or with non-zero biasing of the device. High resistances and operating the device at anything other than zero bias will drastically reduce the conversion efficiency of the device. Exemplary published reports of conventional MIIM diode devices include A. Singh, R. Ratnadurai, R. Kumar, S. Krishnan, Y. Emirov, and S. Bhansali, “Fabrication and current-voltage characteristics of NiOx/ZnO based MIIM tunnel diode,” Applied Surface Science 334, 197-204 (2015), which is hereby incorporated herein by reference in its entirety, and A. D. Weerakkody, N. Sedghi, I. Z. Mitrovic, H. V. Zalinge, I. N. Noureddine, S. Hall, J. S. Wrench, P. R. Chalker, L. J. Phillips, R.Treharne, K. Durhose, “Enhanced low voltage non linearity in resonant tunneling metal-insulator-insulator-metal nanostructures,” Microelectronic Engineering 14, which is hereby incorporated herein by reference in its entirety.

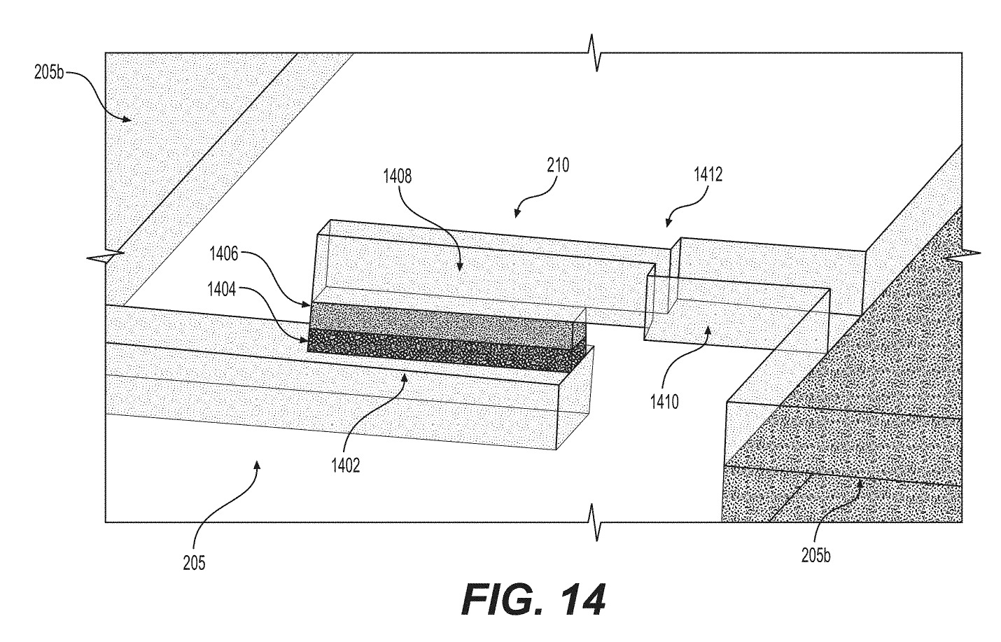

FIG. 14 is a cutaway drawing illustrating one embodiment of connecting a metal-insulator-insulator-diode 210 between a differential transmission line 205 in a method that reduces parasitic reactance of diode 210. MIIM diode 15106 rectifies THz currents which are at the output of impedance matching network 505. As described with respect to FIG. 13A, MIIM diode 210 comprises a first metal layer 1402 (such as aluminum), an insulator layer fabricated over the first metal layer 1404 (such as cobalt oxide), a second insulator fabricated over the first insulator (such as titanium oxide) 1406, and a second metal layer 1408 (such as aluminum) fabricated over the second insulator layer.

Insulator layers 1404 and 1406 are selected with appropriate geometry (e.g., layered) and electron affinity for tunneling to occur. As a result of the tunneling, MIIM diode 210 functions as a rectifier when excited with the terahertz frequency from antenna element 202 over impedance match network 205. A MIM diode may also be used in embodiments. Where a MIM diode is used as diode 210, it would be fabricated without one of the insulating layers.

The vertical construction of diode 210 reduces parasitic capacitance. A transmission line electrical lead interface 1410 is selected to match the cross-sectional area of diode 210 to reduce any leakage across diode 210. This results in a stepped or tapered transition 1412 in interface lead 1410. In an embodiment, no parallel conduction exists between the top transmission line lead 205b and the bottom transmission line lead 205a, except through the diode. The dielectric function of materials, frequency of operation and resulting diode responsivity are all considered in design of the compensation circuit.

### Bowtie Antenna Element with Multi-Stage Compensation

FIG. 15 is illustrates integration of a THz rectifying diode 210 to a differential transmission line 205 having a broad-band transmission line compensation structure using multiple stubs to achieve a multi-pole resonant response and that also serves to boost the voltage to diode 210 according to an embodiment. As shown in FIG. 15 the multi-stage compensation topology comprises various combinations of transmission line components 501a-b, 502a-b, 1502, 1504, 1506, and 1508. Use of multi-stage topologies allows implementation of higher order multi-pole resonant structures such as are designed using discrete components. This enables wide bandwidth compensation. The wider the bandwidth, the more energy is rectified by the tunneling small-signal rectifier (diode). Embodiments are not limited to using combinations of transmission line components, and include other topological embodiments that would be apparent to those skilled in the art.

As shown in FIG. 15, differential leads 205a and 205b act as a dual microstrip transmission line 505 structure that integrates MIIM diode 210 with antenna element 202 to rectify THz signals generated when antenna element 202 is in the presence of heat. In an embodiment, transmission line 205 is designed to implement an impedance transform between antenna 202 and diode 210 to achieve maximum power transfer. For example, in an embodiment, a plurality of stubs 501a, 501b, 502a, and 502b with associated interconnecting transmission line stages 1502, 1504, and 1506 implement a “ganged” L-C filter response. Several dependent geometric parameters are tuned to achieve maximum power transfer and impedance matching. These parameters include: 1) transmission stage lengths; 2) stub positions; 3) stub length and cross section area; and 4) diode position. One way to accomplish this is to use a ‘device level’ full wave simulation of the electromagnetic s-scatter parameters of e-field and h-field. The resulting geometry is specific to the native antenna impedance. Such a compensation circuit provides a conjugate match to native antenna impedance to reduce scatter and reflections. The resulting geometry is also specific to the characteristic impedance of the nonlinear diode load and the capacitance reactance that is introduced by the MIIM structure. Diode distance 1508 is another parameter that can be changed. Adjusting distance 1508 changes the inductance in the diode compensation circuit.

Compensation structures can be tailored to a dynamic range of antenna and diode configurations. For example, the impedance of various MIIM diodes can range from 50 to 10 K ohms with a reactance from −j30 to −j200. This impedance indicates a high capacitance that is intrinsic to MIIM diodes. Both the real and imagery parts of the impedance are compensated for with using compensation structures as described herein.

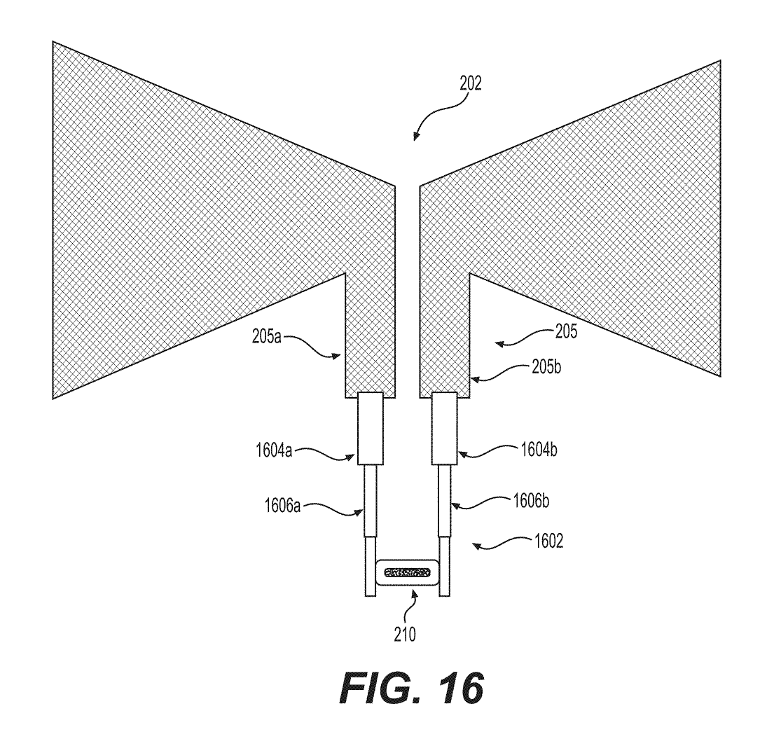

FIG. 16 illustrates a broad-band transmission line compensation structure 1602 that implements multi-stage stepped impedance elements to act as an impedance transformer between the antenna and diode according to another embodiment of the present invention. As shown in FIG. 16, a distributed element filter 1602 provides a step up in impedance for impedance compensation according to an embodiment. Impedance distributed element filter 1062 comprises transmission lines stages 1604a, 1604b, 1606a, and 1606b. A differential transmission line 205 is modified with a reduced trace geometry stage 1602. As shown in FIG. 16 successive stepped stages 1604a and 1606a, and 1604b, and 1606b has narrower traces, and therefore, higher impedance. This stepped-stage design introduces a discontinuity in the transmission characteristics at the steps. The discontinuity can be represented approximately as a series inductor. Multiple discontinuities can be coupled together with impedance transformers to produce a filter of higher order. Effectively then, impedance distributed element filter 1602 is an impedance bridge to couple a load/diode with a much larger impedance than the source. Maximizing the load impedance serves to both minimize the current drawn by the load and maximize the voltage signal across the diode. This voltage boost allows the diode to bias into the optimum nonlinear operating mode. More than two step-down or step-up stages can be included in embodiments of impedance distributed element filter 1602.

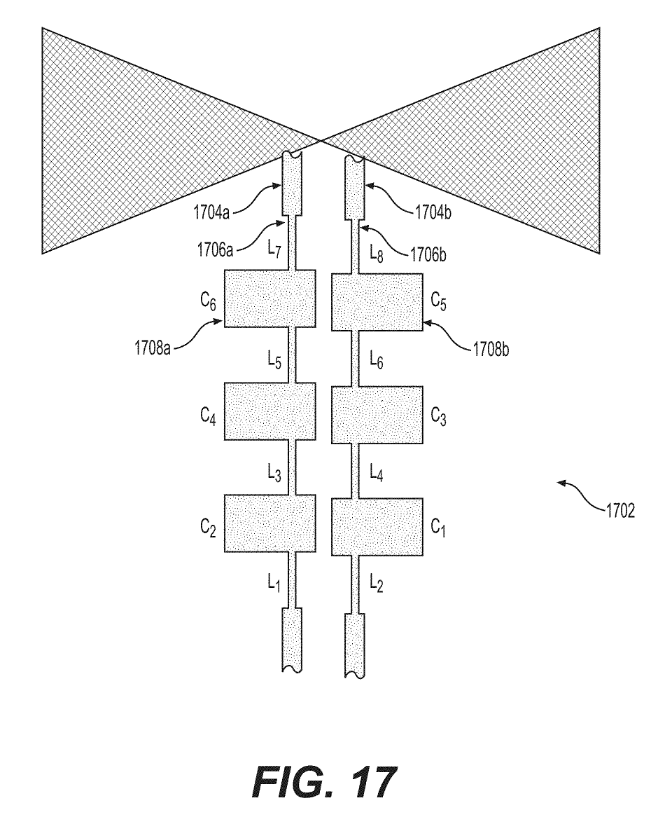

FIG. 17 illustrates how more complex filter responses can be implemented using a ladder topology lumped-element prototype 1702 based on a stepped impedance filter design. As shown in FIG. 17, in an embodiment, ladder topology 1702 comprises alternating sections of high-impedance transmission line stages 1704a-b, higher-impedance transmission line stages 1706a-b and low-impedance transmission line stages 1708a-b. These stages correspond to the series inductors and shunt capacitors. The length of the stages relative to the wavelength of interest determines their function. In an embodiment, each element 1704a-b, 1706a-b, and 1708a-b of each section of the filter is 214 in length. High-impedance sections of the line are made narrow to maximize the inductance, the narrower the section the higher the impedance. Low-impedance sections of the line are made wider to maximize the capacitance, the wider the section the higher the impedance. In embodiments, additional sections having more, fewer, or the same number of alternating varying impedance elements may be added as required for the design characteristics, and performance of the filter. These sections of low and high impedance can be modeled as series inductors L1-L8 and shunt capacitors C₁-C₆ as shown in FIG. 17. In an embodiment, C₁ equals C₆, C₃ equals C₄, C₂ equals C₅, L₁ equals L₈, L₂ equals L₇, L₃ equals L₆, and L₄ equals L₅.

### Other Embodiments for Reactance Tuning

In an embodiment the antenna element 202 is bowtie-type antenna that has a symmetrical structure, with a solid fill of antenna metal. When antenna element 202 has a bowtie structure, fractals and high permittivity dielectrics can be used to increase the refractive index. For example, in an embodiment, the geometry of the bowtie antenna can be altered by removing material from the conductive surface and creating fractalized structure.

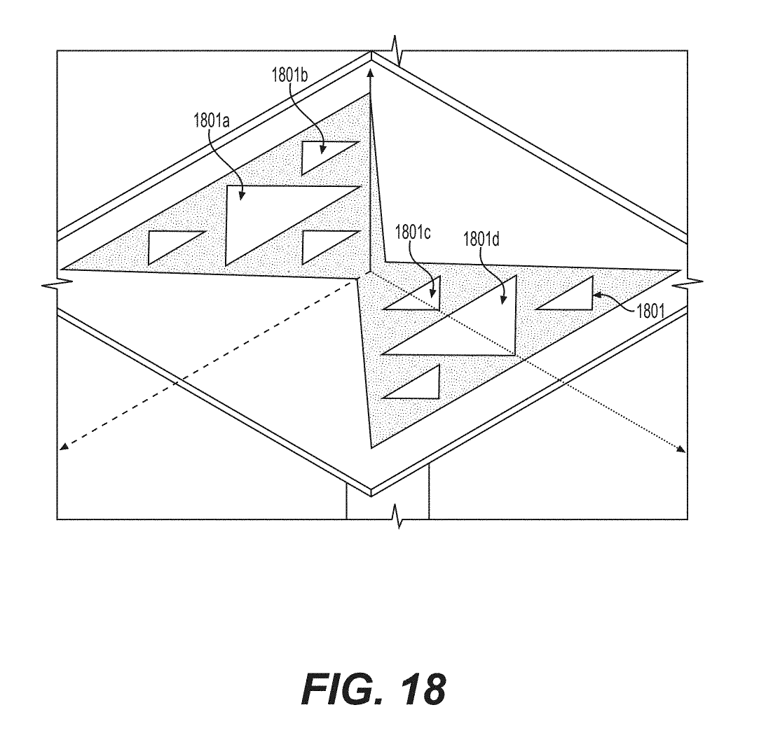

FIG. 18 illustrates a fractal bowtie antenna that provides means to engineer the electron/plasmonic wave conduction path and the relative refractive index of the antenna according to an embodiment. This is an embodiment to tune antenna impedance to counter diode reactance. As shown in FIG. 18 bowtie antenna 1801 has a fractalized surface. By removing regions of conductor, such as removed fractal regions 1801a-d, the electrons must travel further to reach the feed point. This longer current path effectively changes impedance and tunes antenna resonance (that is, narrows the bandwidth). Reactance is tailored by dielectric attenuation of near-field eddy currents. This provides another method to tune antenna impedance to counter diode reactance. Removed fractal regions 1801a-d do not have to be the same size in an embodiment. And, in an embodiment, they may not be symmetric. It may also be advantageous if we desire the antenna to be frequency-selective for detector applications or matching to high Q filter networks.

### Tapered Transmission Line

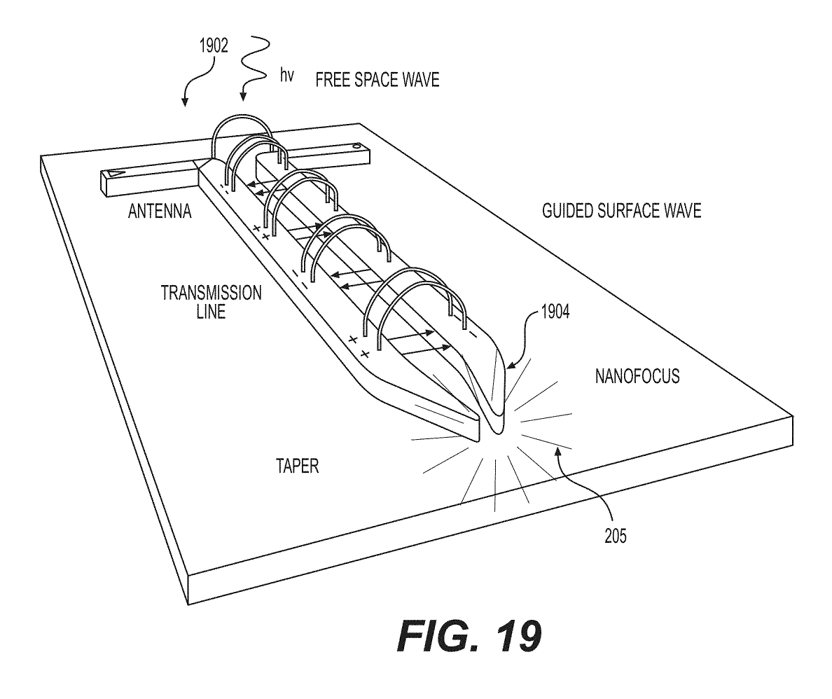

Energy propagating down the transmission line can be further concentrated and focused using a tapered transmission line. FIG. 19 is an orthographic projection illustrating use of a tapered transmission line 1902 to guide and focus surface waves to a nanofocus in the region of the diode according to an embodiment. Infrared energy can be nano-focused to a fraction of the wavelength and overcome diffraction limited effects. In operation antenna element 202 captures infrared light and converts it into a propagating surface wave that travels along transmission line 205. By gradually reducing the width of the transmission line 1902, “tapering,” as shown, for example, by area 1904, the infrared surface wave is compressed to a tiny spot at a taper apex 1906 with a diameter approximately equal to MIIM diode cross section area.

### 3D Metamaterial Fabrication

In an embodiment, a three-dimensional (3D) metamaterial structure is designed to concentrate the electromagnetic field of a heat source. One-dimensional or two-dimensional metamaterial structures may also be used but 3D structures provide the greatest concentration of field.

As described above, embodiments of the present invention couple a rectenna 206 that comprises an antenna element 202 and a diode 210 with a metamaterial 200 to form a metamaterial coupled rectenna 208. As described above, embodiments include a reflector, such as metal reflector 402, such that converting heat into electricity provides improved performance compared to conventional antennas and diodes.

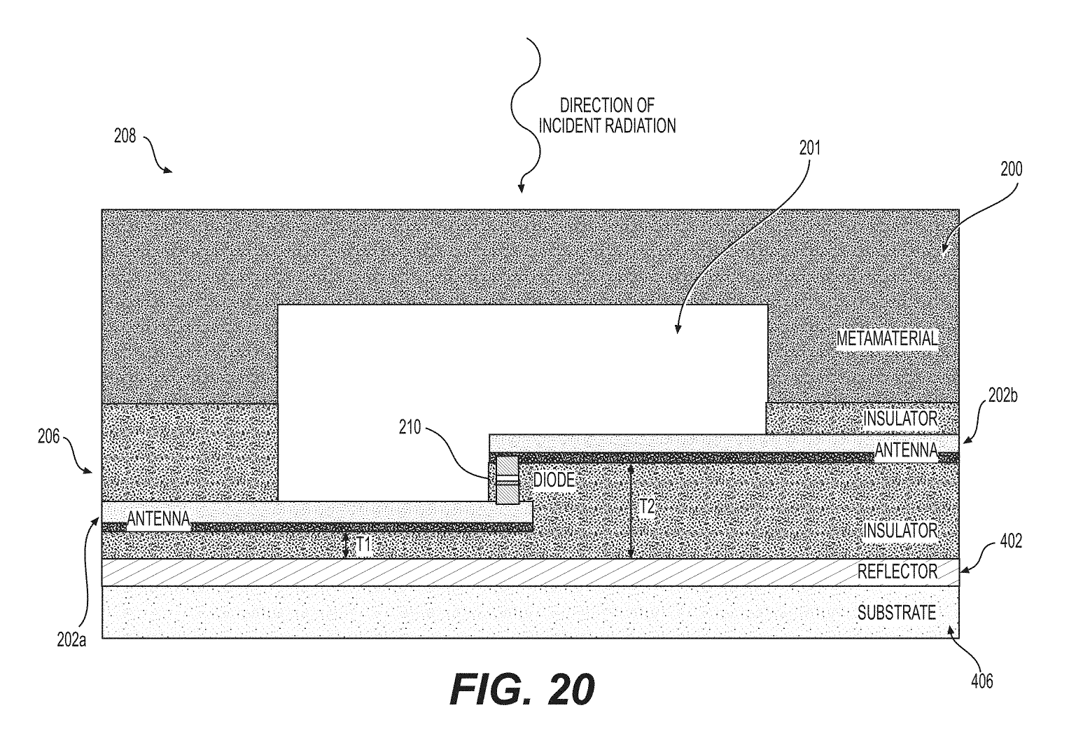

FIG. 20 illustrates a cross sectional diagram of a metamaterial 200 with a metamaterial coupled rectenna 208 that comprises a rectifying antenna (rectenna) 206 with a near field metal reflector 402 over a hole 201 in a metamaterial 200 according to an embodiment. Metamaterial coupled rectenna structure 208 comprises a rectenna 206 placed over a hole 201 in the surface of a metamaterial 200 according to an embodiment. The rectenna comprises antenna components 202a and 202b, such as may be included in antenna element 202 described above, and diode 210. During fabrication, metal comprising antenna element 202 can be deposited in a number ways including, for example, sputtering and evaporation. Thickness is at or approximately 50 mm. Etching and masking are typical fabrication methods. In an embodiment, rectenna 206 includes a MIIM diode as described above with respect to FIGS. 13A-B and 28.

In an embodiment, metamaterial coupled rectenna 208 also includes a reflector 402. Combining reflector 402 with rectenna 206 improves the conversion efficiency of the efficiency of the device. That is, more of the incident radiation is reflected back into rectenna 206, increasing electricity production. Reflector 402 may be made of any suitable material. Such material should be suitable for reflecting infrared radiation in the frequency range of 1 to 30 Terahertz. Suitable reflector materials include most metal films such as aluminum, silver, gold, copper, and nickel. The metal film should be at least 10 Å thick, up to 100 microns thick, most preferably 2000 Å thick. The reflector metal may have another metal film on the side opposite the side of the radiation, to improve adhesion. This adhesion film may be any suitable metal, most preferably titanium or chrome, and the thickness of this adhesion film may be from 10 to 2000 Å, preferably 50 Å. The reflector and/or adhesion metals may be deposited by any suitable method, including evaporation, sputtering, chemical vapor deposition (CVD), or electrodeposition, preferably by sputtering.

Besides metal films, a distributed Bragg reflector (“DBR”) may also be implemented. A DBR comprises paired layers of films, where one layer of the pair has an index of refraction n1 and the second layer has index n2. The thickness of each layer of the pair is generally chosen as in relation to the wavelength of the radiation to be reflected, where n=the index of refraction of the material at the wavelength of interest. There are generally several pairs of films, for example 10 pairs. The reflectivity of the DBR generally increases with increasing number of pairs of films.

An example of a DBR suitable for reflecting 30 THz radiation (λ=9.99 μm) comprises multiple pairs of germanium (Ge) and titanium dioxide (TiO₂) films. The Ge films are 0.73 μm and the TiO₂ films are 1.87 μm thick. Other materials suitable for use as THz DBR reflectors include Si, InGaAs, GaAs, GaN, InGaN, AlAs, AlGaAs, GaP, InGaP, InSb, SiO₂, ZnO, porous SiO₂, Al₂O₃, SiN, porous SiN, Ta₂O₅, HfO₂, MgF, ZrO₂, and Nb₂O₅.

When the reflector is placed within several microns of the antenna (values t1 and t2 in FIG. 20), it is called a near field reflector. The values for t1 and t2 may be from 10 Å to 10 microns, most preferably 1 micron.

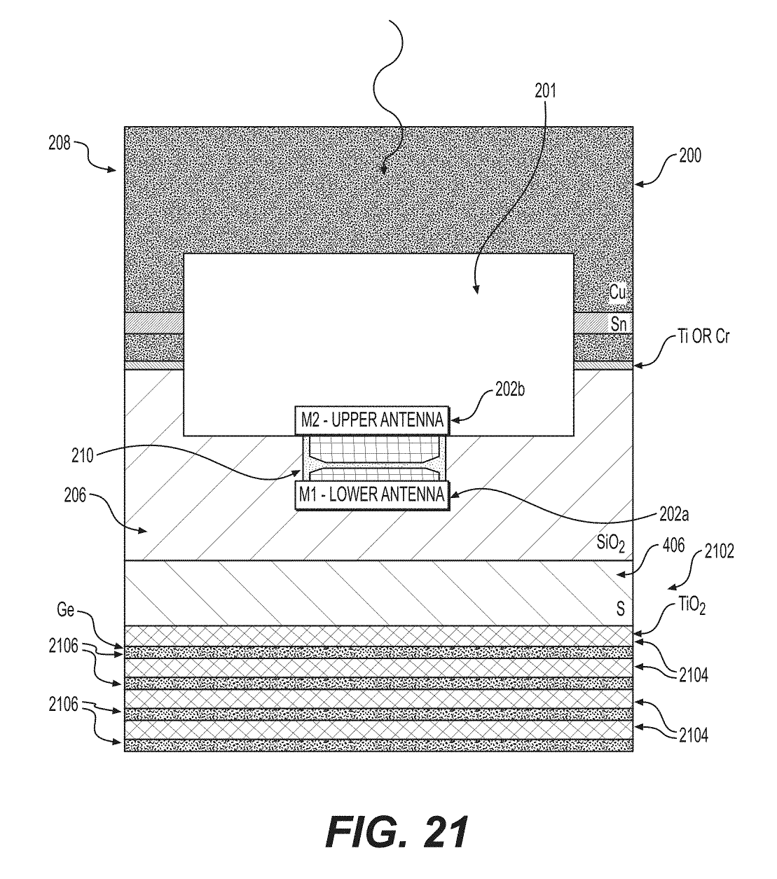

In another embodiment, the reflector may be placed more than several microns away from the rectenna, for example on the backside of the substrate. FIG. 21 illustrates a cross sectional diagram of a metamaterial 200 with a metamaterial coupled rectenna 208 that comprises a rectifying antenna (rectenna) 206 with a far field DBR reflector 2102 over a hole 201 in a metamaterial 200 according to an embodiment. Metamaterial coupled rectenna 208 as illustrated in FIG. 21 comprises a rectenna placed over a hole 501 in the surface of a metamaterial 500 according to an embodiment. Rectenna 206 comprises antenna halves 202a and 202b, such as may be included in antenna element 202 described above, and diode 106. Far field DBR reflector 2102 comprises alternating layers of TiO₂ 2104 and Ge 2106.

### Vertical Confinement and Enhancement of Metamaterial-Generated Surface Plasmons

Embodiments of the present invention use metamaterials as described in U.S. patent application Ser. No. 14/745,299, filed Jun. 19, 2015 (the '299 Application), which is hereby incorporated by reference herein in its entirety. A metamaterial as used in embodiments is an artificial structure that comprises an array of holes fabricated on a metal (such as copper) surface. The holes can be periodic or aperiodic and of the same or varying size. In an embodiment, the holes are sufficiently small to prevent light propagation inside the holes. As a result, the light intensity decays exponentially inside the holes. Under certain conditions, such a metamaterial structure supports surface resonance in which light is concentrated at the surface. This surface resonance has the same characteristics as the surface plasmon resonance that can be observed at a metal-dielectric interface. Due to this similarity, this surface resonance is dubbed a “spoof” plasmon. A key advantage of the metamaterial structure is that the frequency of plasmon resonance can be tailored by the geometrical design of the hole structure. Configuring the geometry of the surface of a metamaterial in this manner, a metamaterial structure supporting a plasmon resonance in the terahertz range was developed. These surface plasmon modes can be excited thermally, which results in thermal radiation that far exceeds the blackbody radiation.

In embodiments, an additional metal 402 is placed on top of the metamaterial surface. Additional metal 402 provides significant improvement over the systems disclosed in the '299 Application as the additional metal acts as a reflector to achieve vertical light confinement and consequently high light intensity near the metamaterial surface. While the metamaterial structure disclosed in the '299 application supports a surface plasmon mode whose field is confined at the surface of the metamaterial and decays exponentially away from the surface, the structure is essentially an open structure. However, this structure is essentially an open structure that relies on the refractive index of the dielectric material for light along the vertical direction (the direction perpendicular to the metamaterial surface). Thus, light confinement in the vertical direction (that is, the direction perpendicular to the metamaterial surface) depends on the refractive index of the dielectric material. Adding an additional metal layer reflector 402 a short distance from the metamaterial surface acts as a reflector to push the field back toward the metamaterial surface, creating vertical confinement. This not only increases the maximum achievable field concentration, but also provides control over the vertical field distribution.

To determine the geometries of the metamaterial structure and offset distance of the reflector, specific modeling of the excitation of the native SP mode can be used. For example, a plane wave incident from the far-field in the (−z) direction can be simulated. While such an optical simulation is computationally efficient, it is limited. For example, while it accurately generates the SP mode of interest when there is no reflector layer, it cannot be used when the reflector layer is present. This is because the incident wave is simply reflected back to the far field before interacting with the metamaterial to generate the SP mode.

As such, a thermal-based model, such as the FDTD Solutions tool www.lumerical.com/tead-products/fttd/) available from Lumerical Solutions, Inc. of Vancouver, British Columbia (www.lumerical.com) can be used to reproduce and extend the results, that is, obtain better, more accurate results. The thermal model simulates the metamaterial blackbody as a collection of randomly oriented dipoles. Modeling the metamaterial blackbody as a collection of randomly oriented dipoles provides a more-accurate representation of the mechanism by which the SP mode is generated (i.e., from within the bulk of the hot metamaterial), and allows for a more accurate prediction of the resulting electric field values.

Confinement and further manipulation of the native surface plasmon (SP) mode in the vertical dimension (perpendicular to the blackbody surface), by use of metal reflector layer 402, has been confirmed by finite element simulations. Preferably, the reflector layer of metal is offset from the blackbody surface by a distance smaller than the vertical extent of the native SP mode. An exemplary geometry is illustrated in FIG. 4. A reflector layer 402 confines the native SP mode to a smaller mode volume that without the reflector layer, which, in turn, creates a greater concentration of electric field. Further, by decreasing the depth of hole 201 initially used to create the metamaterial from deep to shallow, the SP mode can be forced out of the hole. The net effect of tuning these parameters (reflector layer 402 offset and hole 201 depth) is a waveguide-like structure capable of confining and enhancing the already very strong electric field of the SP mode.

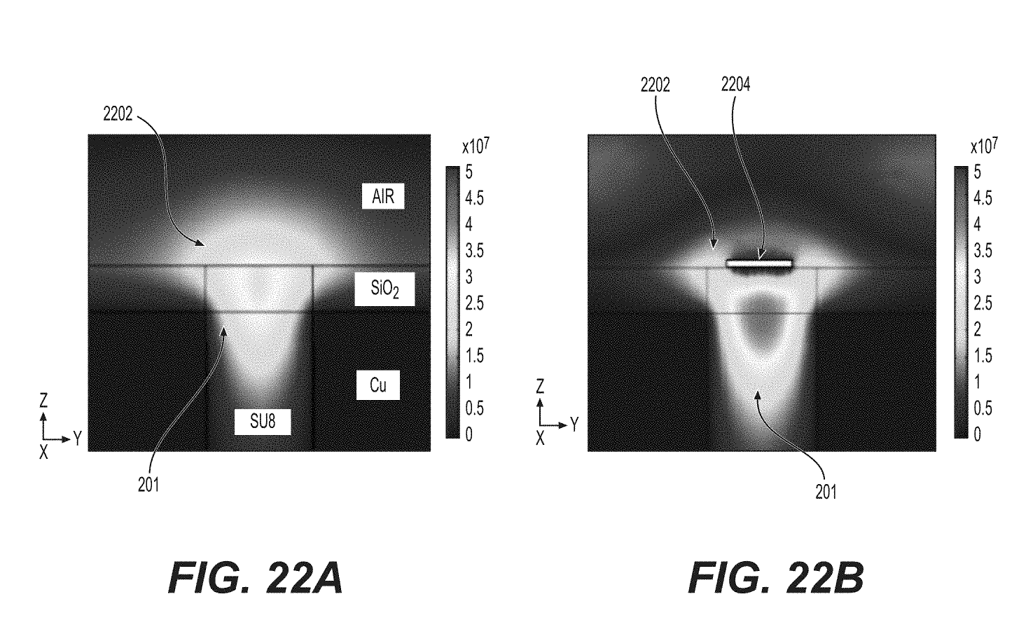

The addition of a reflector, whether an additional metal layer reflector 402 or DBR reflector 2102 provides a significant improvement due to vertical light confinement and consequently high light intensity near the metamaterial surface. FIGS. 22A and 22B illustrate this phenomenon of embodiments of the present invention. FIG. 22A illustrates the electric field magnitude (V/m) of SP modes generated using far-field excitation of a metamaterial (patterned Copper (Cu)) surface with no reflector. As can be seen in FIG. 22A, confinement in the vertical direction is controlled solely by the metamaterial geometry as shown by area 2202. FIG. 22B illustrates the electric field magnitude (V/m) of SP modes generated using far-field excitation of a metamaterial (patterned Cu) surface that are significantly confined in the vertical direction using a reflector 2204. Reflector 2204 can be a metal layer reflector 402 or a DBR reflector 2102. Further confinement is possible by making the hole 201 (SU8) shallower.

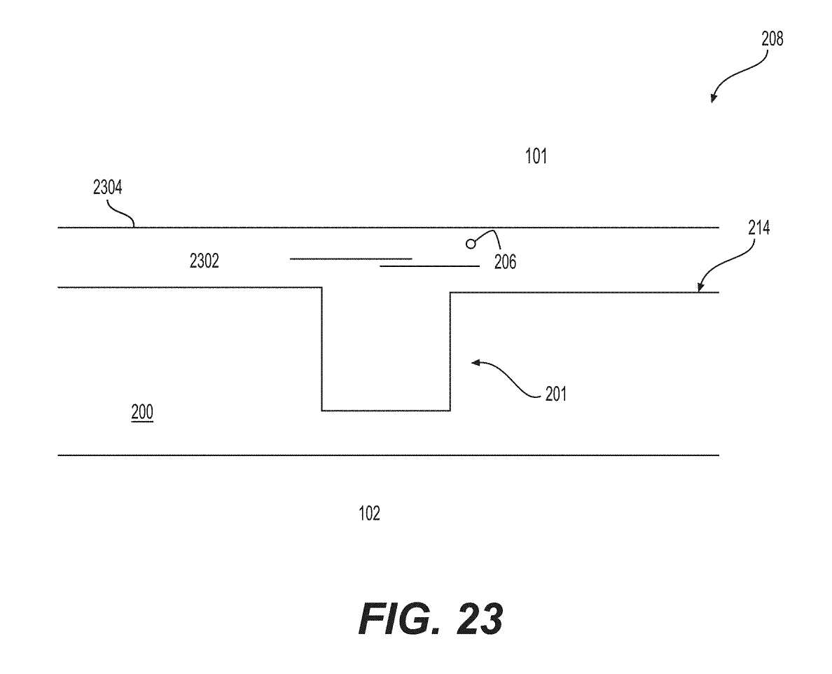

FIG. 23 illustrates a cross section of 3D metamaterial 200 with metamaterial coupled rectenna 208. As shown a rectenna 206 is placed above hole 101 in surface 214 of 3D metamaterial 200, and between metamaterial surface 214 and a reflector 2304. Reflector 2304 can be a metal layer reflector 402 or a DBR reflector 2102.

In operation, a hot source 102 heats metamaterial 200. Representative hole 201 resonates creating a hot spot which is designed to reach a near maximum in the region of rectenna 206. Rectenna 206 is positioned in region 2304, which may be SiO₂ or, in other embodiments, air or vacuum. Embodiments using air or vacuum would require a support pedestal in the region above rectenna 206. A cool side source 101 provides for a thermal gradient to cause heat to flow from hot source 102 to cold source 101.

### Rectifying Antenna with Backside Contacts

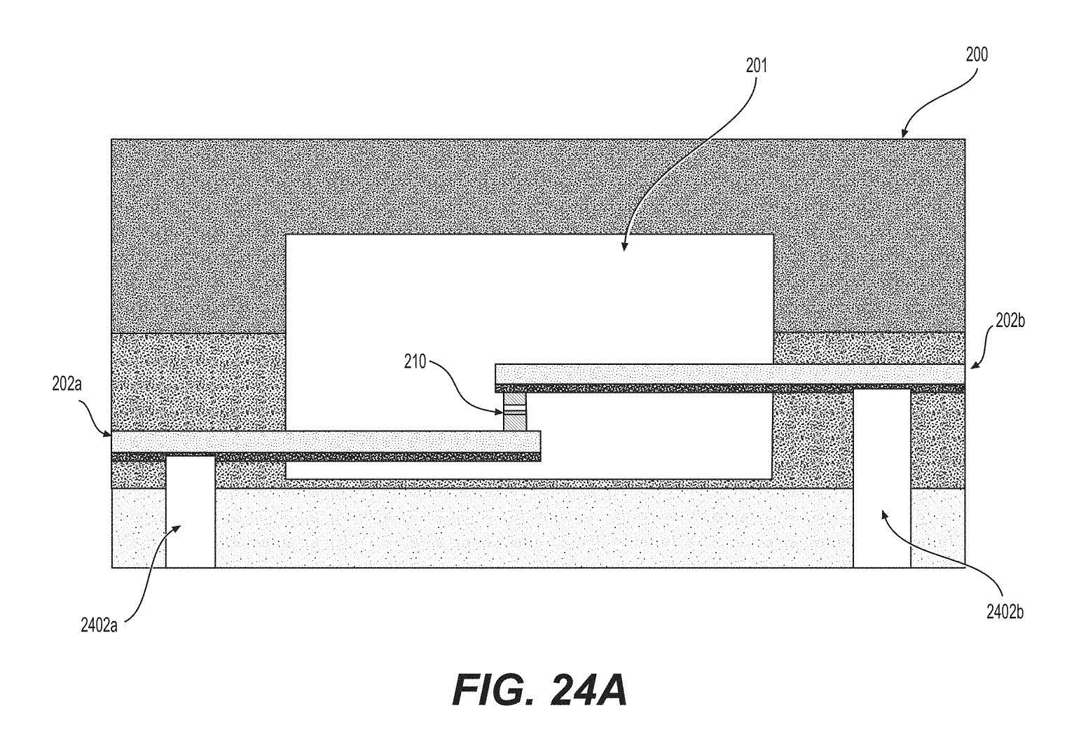

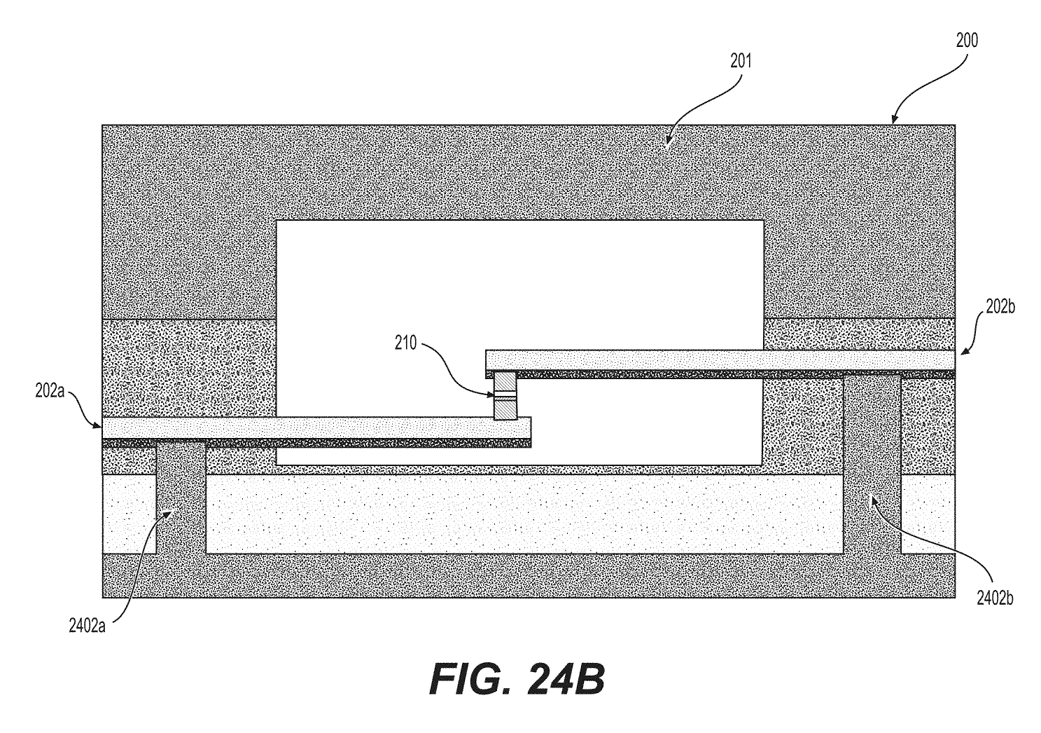

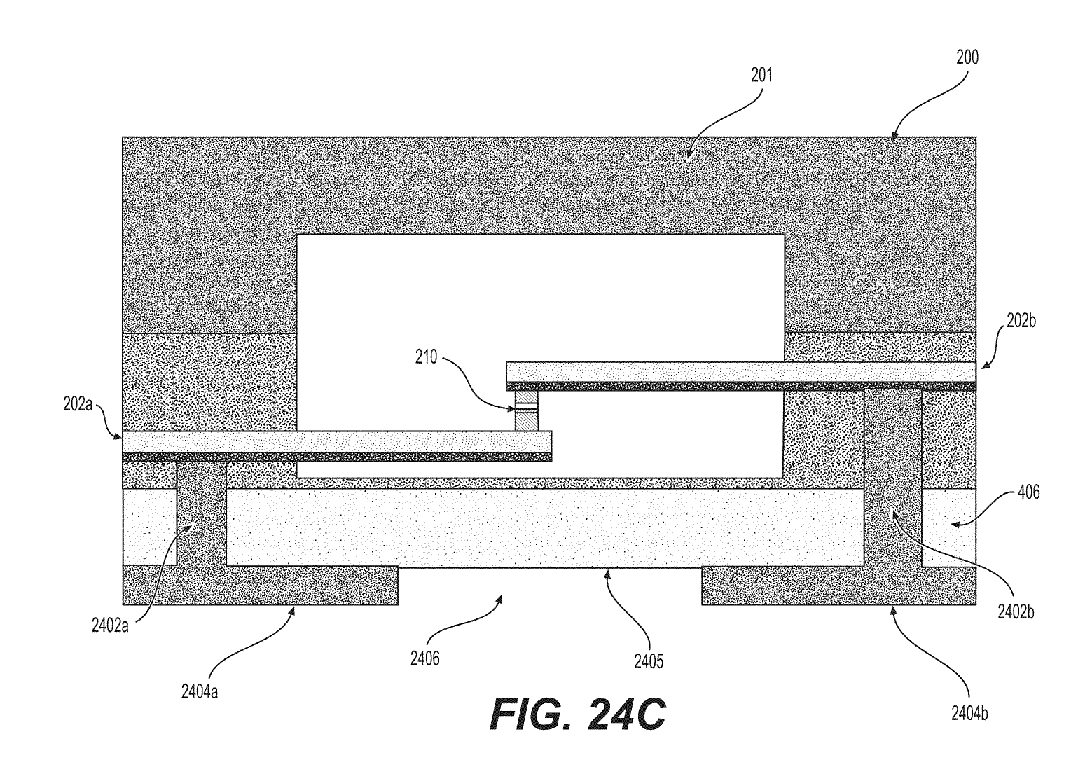

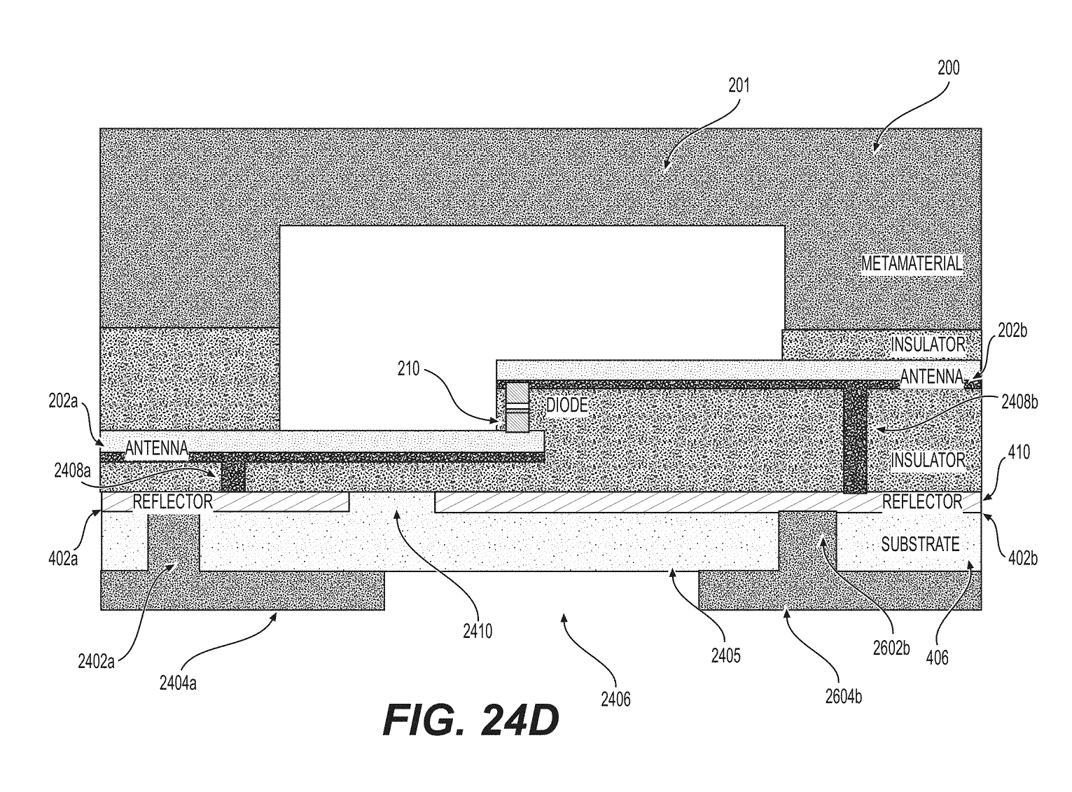

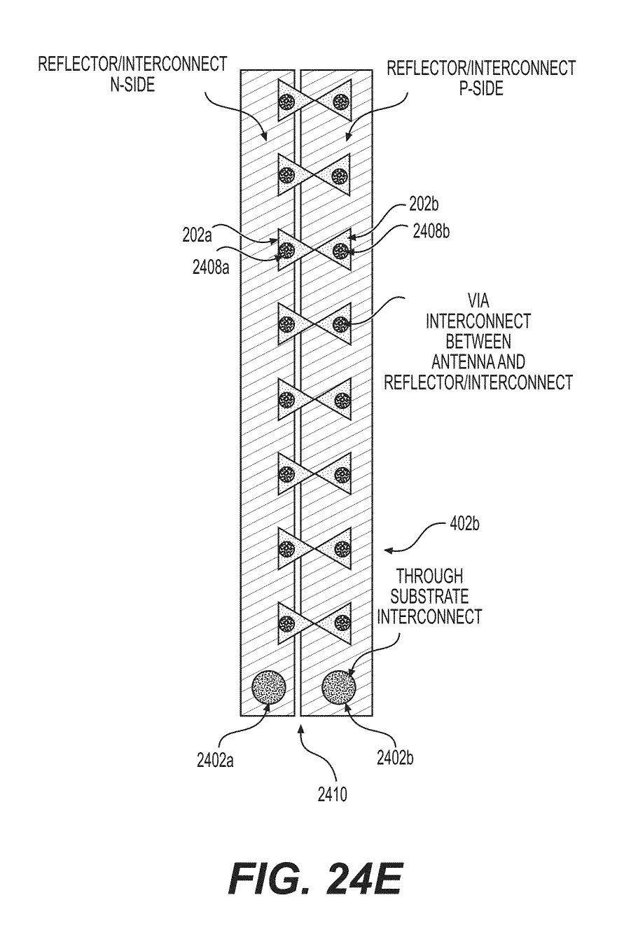

FIG. 24A illustrates a rectenna during fabrication to show vias 2402a and 2402b etched or ablated through the substrate. FIG. 24A illustrates how conductive interconnects are incorporated on the side of the device opposite the heat source, that connect the device to the outside world according to an embodiment. Placing the interconnects on the side opposite the heat source increases the conversion efficiency of the device. This is because to minimize the resistance of the interconnects, such interconnects are preferably thick and/or wide metal films. As metal films reflect heat, placing them on the same side of the device as the heat source would result in a lower density of harvesting devices, because reflection of heat would preclude placing harvesting devices underneath them.

Fabrication of a single device has been described above. It should be understood that many harvesting devices, for example thousands or millions, can be fabricated simultaneously on the same substrate. In an embodiment, vias 2402a and 2402b are etched from the backside of the substrate to each half of antenna element 202, antenna halves 202a and 202b, one antenna half connecting the n-side of the diode 210 (for example antenna half 202a), the other antenna half connecting to the p-side of the diode 210 (for example, antenna half 202b) as shown in FIG. 24A. In an embodiment, vias 2402a and 2402b do not access antenna halves 202a and 202b themselves, but rather access other lateral interconnects that connect to antenna halves 202a and 202b. Vias 2402a and 2402b may be formed by standard lithographic patterning and etching, or, in an alternative embodiment, may be formed by laser ablation. In an embodiment, for 5 THz signals, the vias are at or approximately 2 μm.

FIG. 24B illustrates a rectenna during fabrication after metal deposition of the eventual backside contacts by filling vias 2402a and 2402b with a conductive material. As shown in FIG. 24B after vias 2402a and 2402b are formed, in an embodiment, they are filled with a conductive material, such as a metal. The metal may be copper, tungsten, aluminum, titanium, chrome, titanium nitride, tantalum, tantalum nitride, or combinations of such metals or other metals. The metal may be deposited by any means, including evaporation, sputtering, CVD, or electrodeposition. In an embodiment, for example, the metal is a sequence of titanium, tantalum nitride, and copper. In such embodiment, the titanium and tantalum nitride films are deposited by sputtering, and the copper film is deposited by a combination of sputtering and electrodeposition.

FIG. 24C illustrates a rectenna during fabrication illustrating after formation of distinct interconnects on the backside of the substrate. FIG. 24C illustrates that after metal deposition to fill vias 2402a and 2402b, in an embodiment, interconnects 2404a and 2404b on the backside 2405 of substrate 406. Substrate 406 may also be called the metamaterial metal if the metamaterial is fabricated separately from the substrate and bonded to a substrate. For example, in FIG. 23 substrate is 102 and metamaterial is 200) may be further patterned and etched as shown in etched area 2406 forming patterned interconnects 2404a and 2404b. In an embodiment, instead of patterning and etching, interconnects 2404a and 2404b on the backside 2405 of the substrate 406 may be formed by a damascene method.

In an alternative embodiment, as described above, to improve performance, a metal reflector 410 is placed between substrate 406 and rectenna 206. FIG. 24D illustrates a rectenna 208 with a reflector 402 that also serves as a local interconnect, combined with global interconnects on the backside of the substrate (side view). FIG. 24E illustrates a top down view of a group of 8 rectifying antennas that are locally connected in series by two reflector/local interconnects between the substrate and rectifying antenna, each reflector interconnect connecting either the p-side or n-side of the diodes. As shown in FIGS. 24D-E, metal layer reflector 402 is divided into two reflector components, 402a and 402b, used as a local interconnect to connect one side of a plurality of harvesting devices, for example 8 harvesting devices. Vias 2408a and 2408b are then used to connect to respective reflector components 402a and 402b of reflector 402 to connects 8 devices together as shown in. A gap or disconnect 2410 is formed in reflector 402 to form the two reflector components 402a and 402b. A via interconnect 2408a is formed to connect antenna component 202a of the plurality of harvesting devices to reflector component 402a, and a via interconnect 2408b is formed to connect antenna component 202b of the plurality of harvesting devices to reflector component 402b. Thus, there is via interconnect 2408a between metal reflector component 402a to each antenna component 202a of each of the 8 devices, and a via interconnect 2408b between reflector component 402b to each antenna component 202b of each of the 8 devices. In this manner, reflector components 402a and 402b acts as a backplane for antenna components 202a and 202b respectively of the 8 harvesting devices. In this manner, the number of vias 2402a and 2402b is minimized, reducing costs and increasing the structural integrity of the integrated devices. Rectenna Input Voltage Boost and Diode Capacitance Compensation

The basic rectenna circuit is well understood. It comprises an antenna that produces a small voltage (˜1 mV) at a high frequency (>1 THz). The efficiency of conversion is low for several reasons. For example, the diode nonlinearity occurs at a significantly higher voltage (˜100 mV) than the voltage output of the antenna (˜1 mV). While the voltage at which the knee of the diode nonlinearity occurs can be reduced, the amount of reduction this reduction is limited by the band gaps of elements and the ease of manufacture of the various elements.

Another reason for the low efficiency of power conversion is the capacitance of the diode. At the high frequency of operation (>1 THz) the capacitance of the diode effectively shorts out the diode nonlinearity. That is, the conductance of the capacitance of diode 106 is greater than the forward impedance of the diode. This can be interpreted as a shorting path since the capacitance of the diode conducts in both directions.

A further reason for low power output is that maximum power output can only be obtained if the current taken from the antenna is a sinewave that is in phase with the THz sinewave voltage of the antenna. In the context of AC mains this is called power factor, but it has not been addressed in the prior art. In the context of solar panels this is called MPPT (maximum power point tracking). Only maximizing the efficiency of power converter without addressing this issue does not produce the maximum output power. In other words, maximum power has to be extracted from the antenna as well as maximizing the power conversion efficiency of the power conversion.

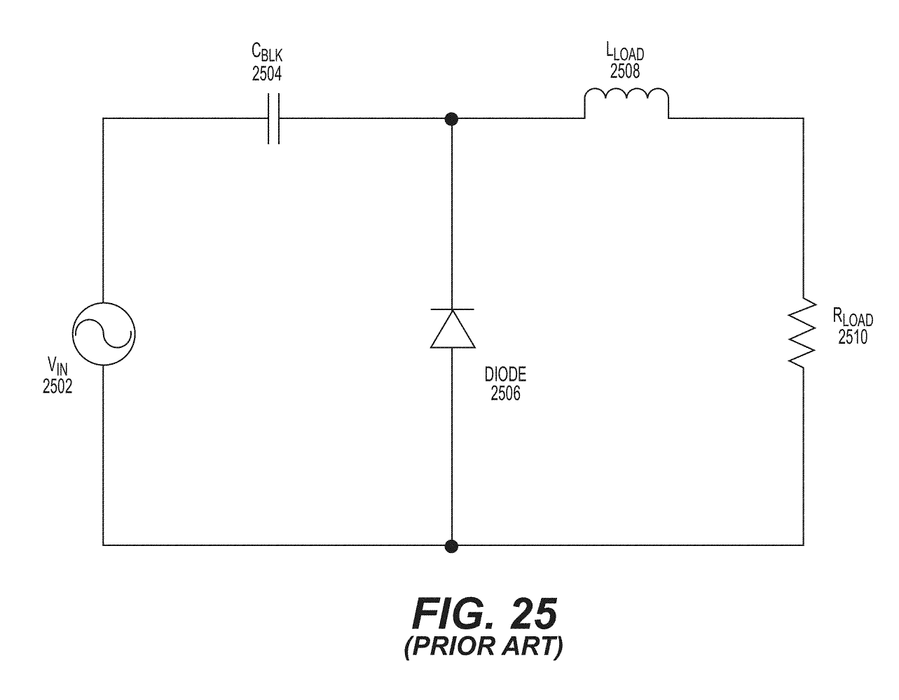

FIG. 25 is a schematic diagram of an equivalent circuit that illustrates a basic conventional rectenna circuit. In FIG. Comp 1, an AC voltage source V_{IN} 2502 represents antenna 202. A capacitor C_{BLK} 2504 decouples AC voltage source 2502 from a diode 2506, which supports current in a single direction. Diode 2506 is a high-speed diode that provides the rectification of AC voltage source 2502, such as diode 210. An inductor L_{LOAD} 2508 is connected to diode 106 and supports a constant current that feeds a load resistance R_{LOAD} 2510. In implementation, inductor L_{LOAD} 2508 may not necessarily resemble a conventional low frequency coiled inductor. For example, a very small length of conductor can be used as an inductor at the high frequency THz associated with embodiments of the present invention. For instance, the small conductor length relative to a wavelength of 10 um might be 2 um to 4 um. Determination of the precise length of a conductor and its function in a circuit are determined by results of simulation.

FIG. 26 is a schematic diagram of an equivalent circuit that illustrates a basic two-pole resonant structure 2606 implemented with discrete components, in accordance with an embodiment of the present invention. In embodiments, compensation two-pole resonant structure 2606 is implemented using transmission line components. An AC voltage source V_{IN} 2502 represents antenna 202. Capacitor C_{BLK} 2504 decouples ac voltage source 2502 from a diode 2506 which supports current in a single direction. Diode 2506 is a high-speed diode which provides the rectification of ac voltage source 2502, such as diode 210. An inductor L_{LOAD} 2508 is connected to diode 106 and supports a constant current that feeds a load resistance R_{LOAD} 2510. In implementation, inductor L_{LOAD} 2508 may not necessarily resemble a conventional low frequency coiled inductor. For example, a very small length of conductor can be used as an inductor at the high frequency THz associated with embodiments of the present invention. For instance, the small conductor length relative to a wavelength of 10 um might be 2 um to 4 um.

In an embodiment, Two-pole resonant structure 2402 is a tank circuit comprised of an inductor Lᵣₑₛ 2602 and a capacitor Cᵣₑₛ 2604 combined to form a tank circuit 2406. Tank circuit 2606 performs an impedance match between antenna voltage source V_{IN} 2502 and diode 2506. Tank circuit 2602 also trades current for voltage thus boosting the voltage of the antenna voltage source V_{IN} 2502. Thus, tank circuit 2602 represents a transmission line 205 with a single discontinuity as explained above. Boosts of 5× to 10× are possible. Boosted voltage is advantageous to rectenna operation since the diode 106 operates best in generally higher voltage ranges than the 1 mV to 20 mV than antenna element 202 might supply by itself

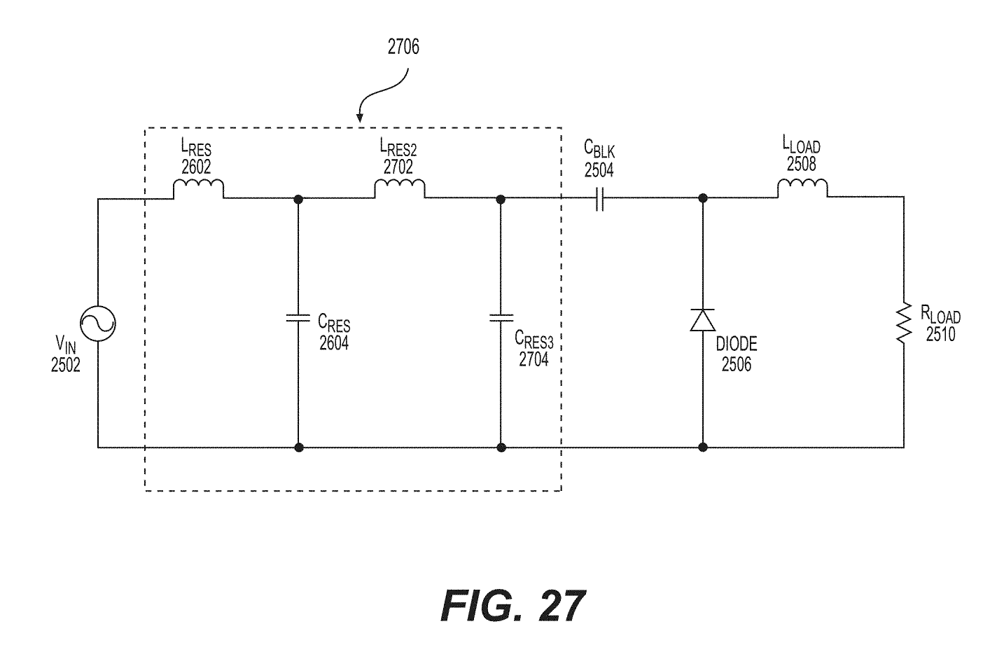

FIG. 27 is a schematic diagram of an equivalent circuit that illustrates a higher order four-pole resonant structure 2706 implemented with discrete components according to an embodiment of the present invention. In embodiments, compensation two-pole resonant structure 2706 is implemented using transmission line components. In an embodiment, four-pole resonant structure 2706 comprises inductor an L_{RES} 2602 and a capacitor C_{RES} 2604 and an inductor L_{RES2} 2702 and a capacitor C_{RES2} 2704 to form a cascade of two L-C structure tank circuits 2706. Cascaded tank circuits 2706 can provide greater boost of voltage by a factor of 100 with a bandwidth of 10%. Thus, cascaded tank circuits 2706 represent a transmission line 205 with a multiple discontinuities as explained above. The output of the L-C structure cascade 2706, C_{RES2} 2704, is capacitively connected to diode 2506 using the capacitor C_{BLK} 2504. As described above, diode 2506 is inductively coupled to the load R_{LOAD} 2510 using inductor L_{LOAD} 2508.

FIG. 28 is an exemplary voltage vs. current characteristic curve 2802 of a typical diode 210 used in a circuit representing rectenna 206 according to an embodiment of the present invention. The x-axis is the diode voltage V_{BIAS} 2804 while the y-axis is the diode current I_{TUNNEL} 2805. The diode characteristic can be approximated by a forward resistance R_{F} 2806 and a reverse resistance RR 2808. As indicated by curve 2802 current through diode 106 stays very low and does not approach the current corresponding to the forward resistance until the voltage across diode 106 reaches a threshold voltage V_{T} 2810. For many diodes the threshold voltage V_{T} 2810 may be as high as 100 mV. The input boost structures described above, such as transmission lines designed with one or more discontinuities may be used to boost the antenna AC voltage V_{IN} 2502 to a voltage greater than V_{T} 2810 at the diode 2506.

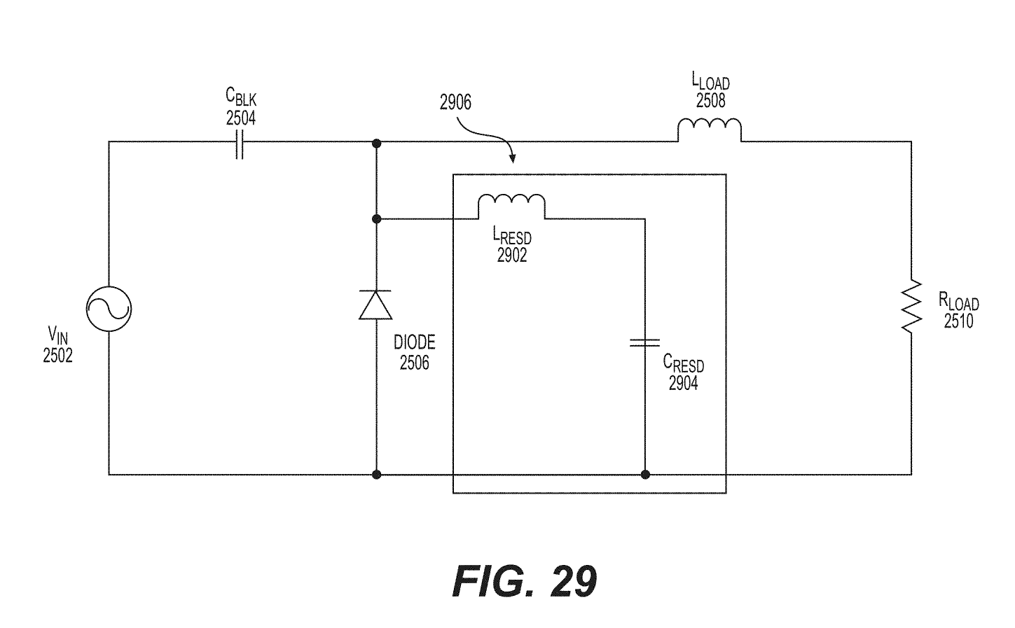

FIG. 29 is a schematic diagram of an equivalent circuit that illustrates a two-pole compensation structure 2906 for diode 2506 capacitance implemented with discrete components, in accordance with an embodiment of the present invention. In embodiments, compensation structure 2906 is implemented using transmission line components. Compensation structure 2906 is comprised of inductor L_{RESD} 2902 is connected in series with a capacitor C_{RESD} 2904. The inductor L_{RESD} 2902 and capacitor C_{RESD} 2904 compensation structure 2906 is connected in parallel to diode 2506. The component values L_{RESD} 2902 and C_{RESD} 2904 of the compensation structure are chosen to have a net inductance that substantially cancels the capacitance of diode 2506 at the frequency of the antenna AC voltage source VIN 2502. Compensation structure 2906 reduces the impact of diode 2506 by a factor of about 10 over a 10% bandwidth of the antenna voltage source V_{IN} 2502.

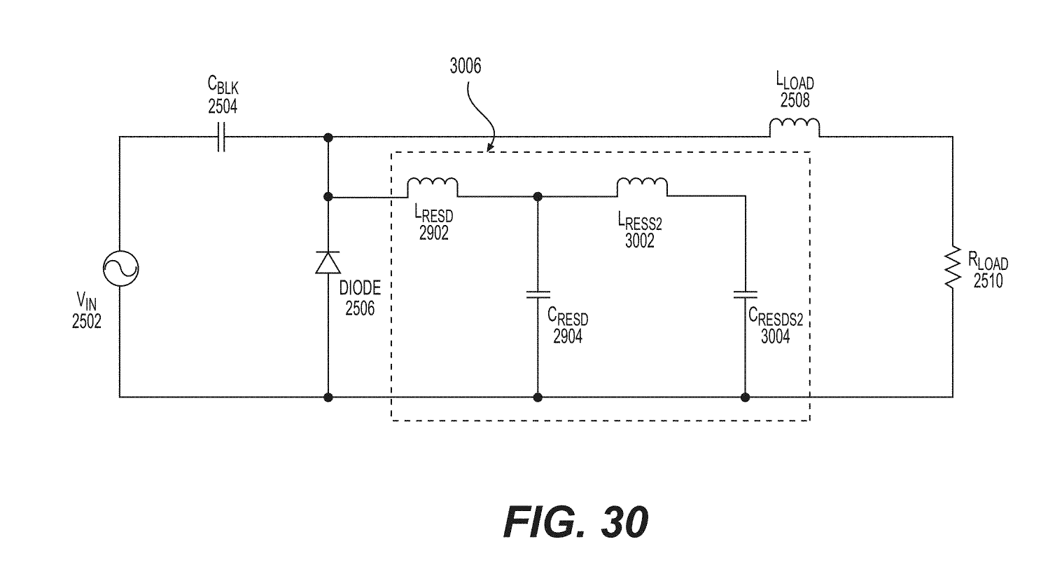

FIG. 30 is a schematic diagram of an equivalent circuit that illustrates a four-pole compensation structure 3006 for diode capacitance implemented with discrete components, in accordance with an embodiment of the present invention. In embodiments, compensation structure 3006 is implemented using transmission line components. In this implementation, compensation structure 3006 comprises a series connection of two L-C compensation structures the first L-C compensation structure comprising inductor L_{RESD} 2902 and capacitor C_{RESD} 2904, and the second L-C compensation structure comprising an inductor L_{RESDS2} 3002 and a capacitor C_{RESDS2} 3004. The remaining circuit is substantially similar to the circuit described above in FIGS. 25 and 29. Adding a second compensation circuit takes the incoming voltage and current to it, and trades current for voltage again to, in effect, create a second boost of voltage. It has the side effect of reducing the bandwidth of the resonance.

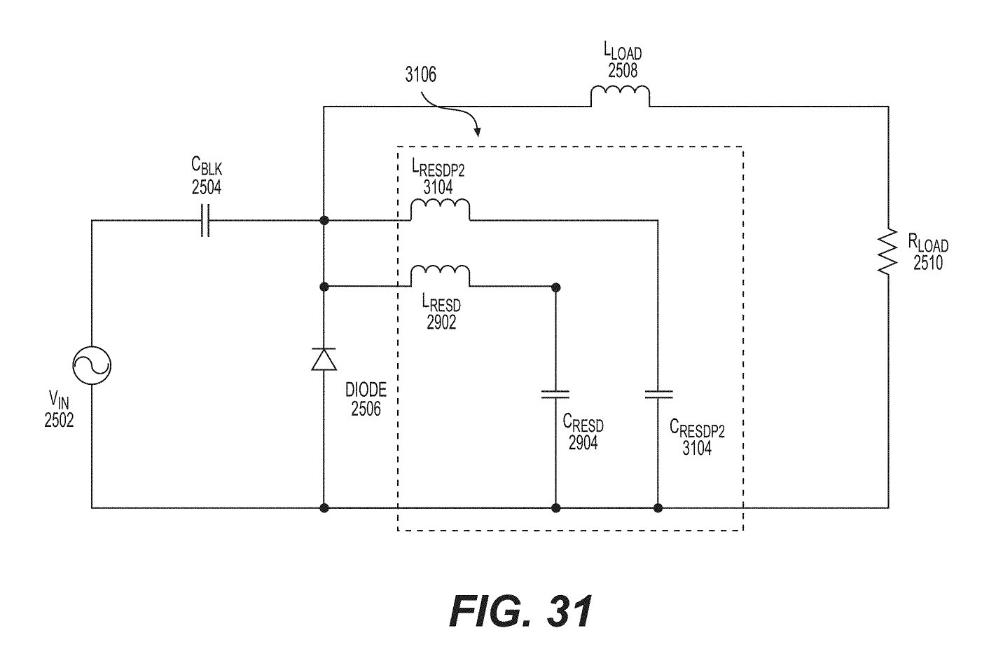

FIG. 31 is a schematic diagram of an equivalent circuit that illustrates a four-pole compensation structure 3106 for diode capacitance implemented with discrete components, in accordance with another embodiment of the present invention. In embodiments, compensation structure 3106 is implemented using transmission line components. As illustrated in FIG. 31, compensation structure 3106 comprises a parallel connection of two L-C structures, the first L-C compensation structure comprising inductor L_{RESD} 2902 and capacitor C_{RESD} 2904 and the second L-C compensation structure comprising an inductor L_{RESDP2} 3102 and a capacitor C_{RESDP2} 3104. The remaining circuit is substantially similar to the circuit in FIG. 30. As explained above, the addition of the second compensation circuit compensates for the capacitance of the diode.

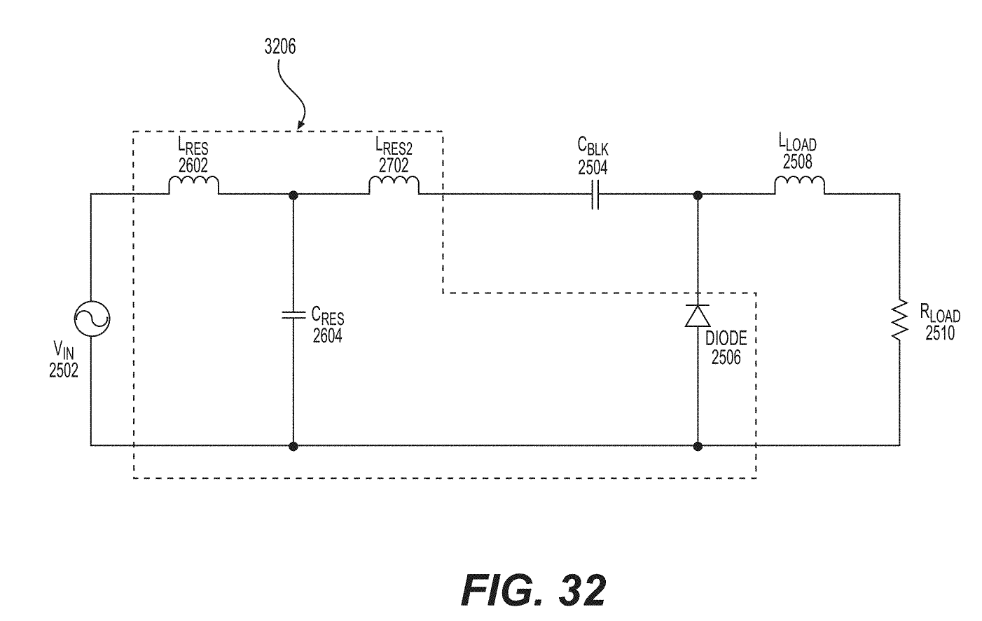

FIG. 32 is a schematic diagram of an equivalent circuit that illustrates a modified four-pole resonant structure 3206 implemented with discrete components, in accordance with an embodiment of the present invention. In embodiments, compensation structure 3206 is implemented using transmission line components. In this case, the parasitic capacitance of diode 2506 is used as an element in a four-pole lumped element model. Thus, four-pole resonant structure 3206 comprises a first tank circuit comprising inductor L_{RES} 602 and capacitor C_{RES} 2604, and a second tank circuit comprising inductor L_{RES2} 2702 and the parasitic capacitance of diode 2506. The capacitance of diode 2506 is fairly constant with little variation over temperature and process. The remaining three components of four-pole resonant structure 3206, inductor L_{RES} 2602, inductor L_{RES2} 2702 and capacitor C_{RES} 2604, are chosen to maximize output power delivered to load R_{LOAD} 2510. Significant voltage boost ratios greater than 10 and cancellation of the diode capacitance are achievable. This results in increasing the output power and allows the use of diodes with capacitance such that the capacitive current is comparable to or even greater than the diode forward current. In absence of compensation of the diode capacitance, the capacitance acts to short out the diode action greatly decreasing the output power.

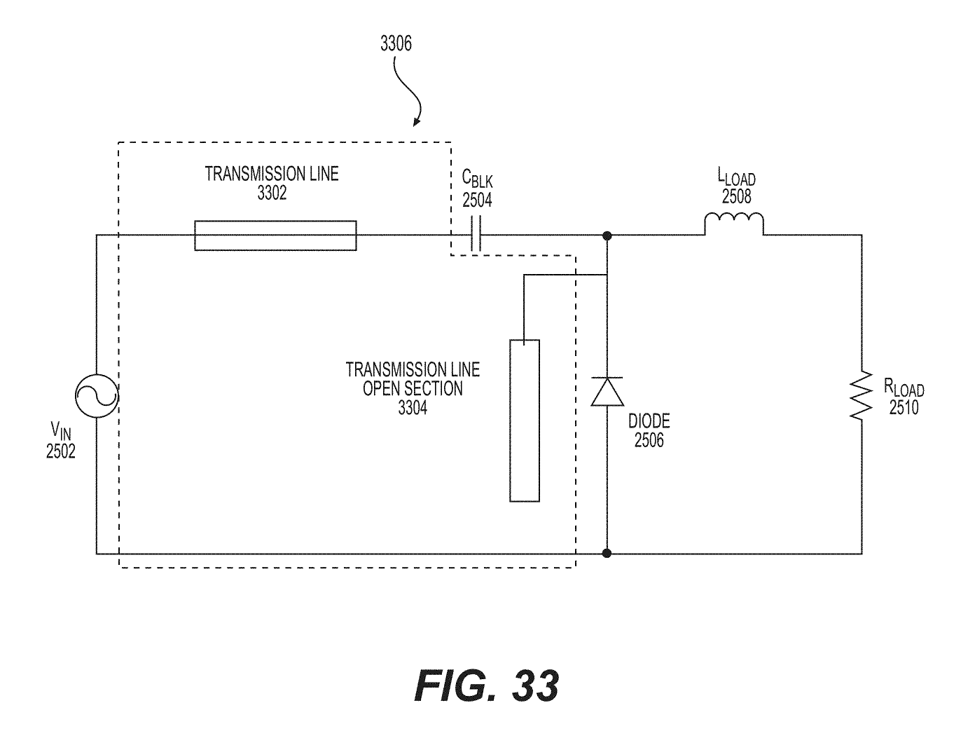

FIG. 33 is a schematic diagram of an equivalent circuit that illustrates an input impedance boost structure and diode capacitance compensation circuit 3306 implemented using transmission line components, in accordance with embodiments of the present invention. As illustrated in FIG. 33, impedance boost and capacitance compensation structure 3306 comprises a series transmission line 3302 to provide an input impedance boost. The diode capacitance is compensated using an open transmission line structure 3304 as described. The parallel combination of the diode 2506 capacitance and the open transmission line structure 3304 is an open circuit at the frequency of the antenna AC voltage source V_{IN} 2502. This is illustrative of how all the circuits described herein may be implemented via transmission line structures as described above.

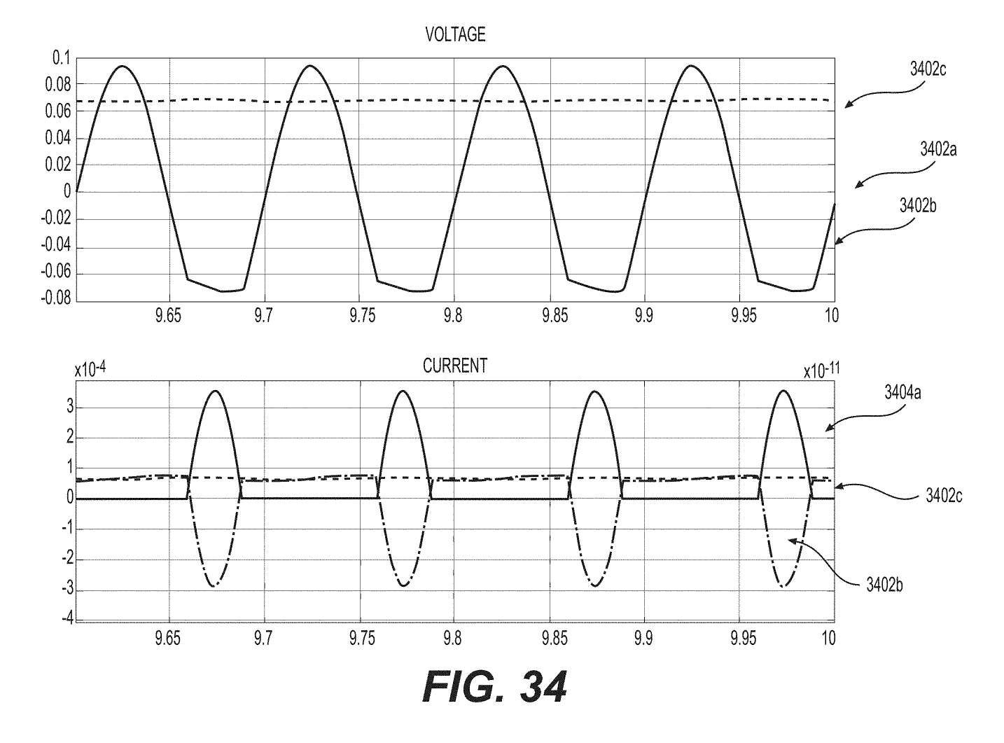

FIG. 34 shows simulated voltage and currents corresponding to a conventional rectenna circuit, whose equivalent circuit is illustrated in FIG. 25, that is, without compensation circuitry described herein. The diode i-v characteristic curve was chosen to be near ideal to illustrate the inherent limitations of this circuit independent of imperfections with diode 2506. Three voltage input curves 3402a, 3402b, and 3402c are illustrated with corresponding diode current outputs 3404a, 3404b, and 3404c, wherein current 3404a corresponds to voltage 3402a, current 3404b corresponds to voltage 3402b, and current 3404c corresponds to voltage 3402c. The current waveform out of the source is not sinusoidal and not in phase with the voltage. Therefore, as explained above, power output is not the maximum output possible even if the diode were ideal. That is, the currents are poorly behave for the power output of the circuit.

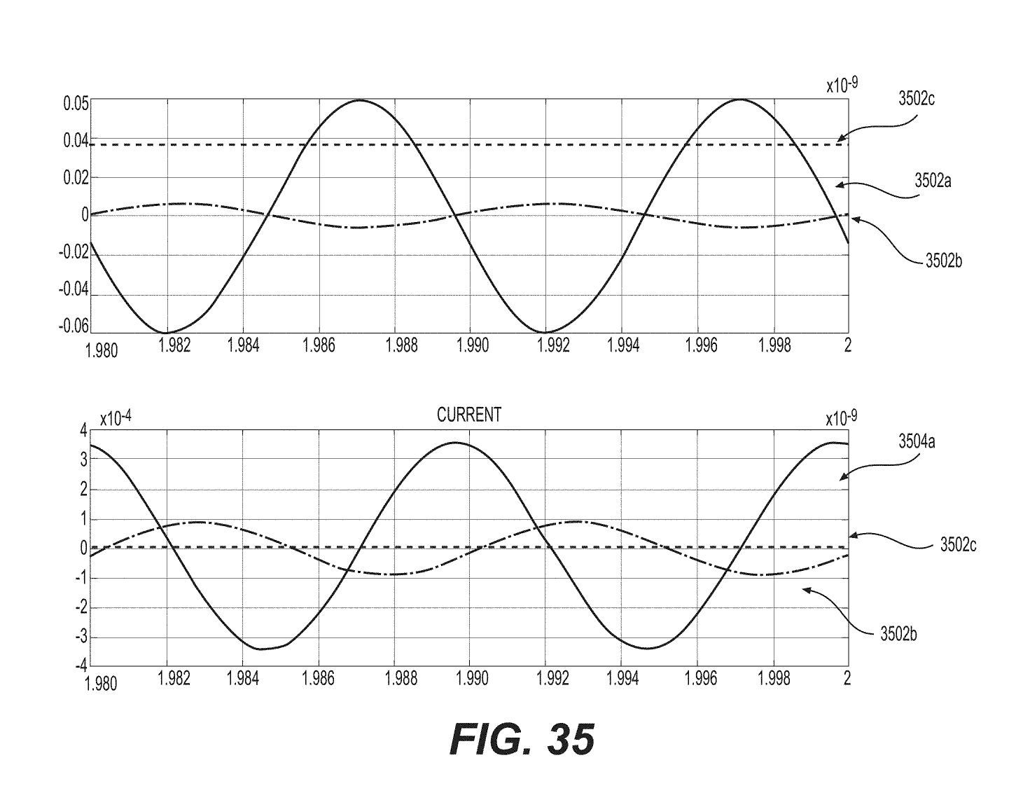

FIG. 35 shows simulated voltage and currents corresponding to the circuit of FIG. 32, that is, with the addition of compensation circuitry (in this case, 2 tank circuits, one using the parasitic capacitance of diode 2506) according to an embodiment of the present invention. The diode i-v characteristic curve was chosen to be near ideal to illustrate the improvement of this circuit independent of imperfections in diode 2506. Three voltage input curves 3502a, 3502b, and 3502c are illustrated with corresponding diode current outputs 3504a, 3504b, and 3504c, wherein current 3504a corresponds to voltage 3502a, current 3504b corresponds to voltage 3502b, and current 3504c corresponds to voltage 3502c. The current waveform out of the source is sinusoidal and in a good and consistent phase relationship with the voltage for power output. The power output is the maximum output possible if the diode were ideal.

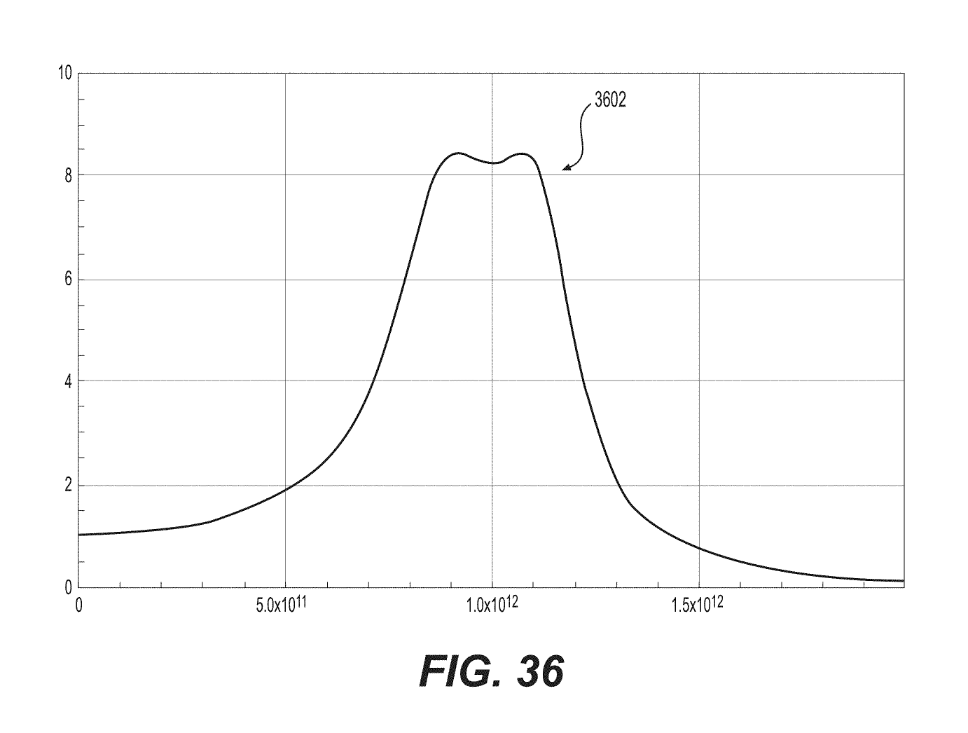

FIG. 36 illustrates the frequency response curve 3602 corresponding to compensation circuit 2706 illustrated in FIG. 27. The four pole LC filter has been chosen to improve the bandwidth of this circuit and to accommodate bandwidth of the source antenna 202.

The structure, manufacture and use of the presently preferred embodiments are discussed in detail. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Various modifications and combinations of the illustrative embodiments, as well as other embodiments of the invention, will be apparent to persons skilled in the art upon reference to the description. In some embodiments, it is therefore intended that the appended claims encompass any such modifications or embodiments.

What is claimed:

1. A metamaterial coupled antenna, comprising:
a metamaterial that generates a spoof surface plasmon in the presence of heat; and
a rectenna, the rectenna comprising:
an antenna element that resonates when the generated spoof surface plasmon has a frequency in the terahertz range; and
a diode coupled to the antenna element over the transmission line to receive the voltage signal and rectify the voltage signal to produce electricity, wherein the diode has a capacitance; and
a transmission line to carry the voltage signal from the antenna element to the diode for rectification , wherein the transmission line is configured to compensate for the capacitance of the diode.

2. The metamaterial coupled antenna recited in claim 1, wherein the diode is a MIIM diode.

3. The metamaterial coupled antenna recited in claim 2, wherein the MIIM diode comprises in a stacked configuration a metal sandwiching two insulators.

4. The metamaterial coupled antenna recited in claim 3, wherein the metal is aluminum and the insulators are cobalt oxide and titanium oxide.

5. The metamaterial coupled antenna recited in claim 1, wherein the metamaterial comprises a plurality of holes, wherein the antenna element is placed over a hole in the metamaterial, further comprising a reflector to confine radiation in the vertical direction.

6. The metamaterial coupled antenna recited in claim 5, wherein the reflector comprises a metal layer.

7. The metamaterial coupled antenna recited in claim 5, wherein the reflector comprises a DBR reflector.

8. The metamaterial coupled antenna recited in claim 7, wherein the DBR reflector comprises alternating layer of titanium oxide and germanium.

9. The metamaterial coupled antenna recited in claim 1, wherein the transmission line is tapered.

10. The metamaterial coupled antenna recited in claim 1, wherein the transmission line is configured to provide a two-pole capacitance compensation.

11. The metamaterial coupled antenna recited in claim 10, wherein two-pole capacitance is implemented as an L-C circuit in parallel with the diode.

12. The metamaterial coupled antenna recited in claim 1, wherein the transmission line is configured to provide a four-pole capacitance compensation.

13. The metamaterial coupled antenna recited in claim 12, wherein four-pole capacitance is implemented as a plurality of series L-C circuits in parallel with the diode.

14. The metamaterial coupled antenna recited in claim 1, wherein the transmission line is configured to use a parasitic capacitance of the diode to compensate for diode capacitance.

15. The metamaterial coupled antenna recited in claim 1, wherein the antenna element comprises a fractalized circuit.

16. The metamaterial coupled antenna recited in claim 1, wherein the transmission line is configured to provide a voltage boost to the voltage signal delivered to the diode.

17. The metamaterial coupled antenna recited in claim 16, wherein the transmission line comprises a tank circuit to provide the voltage boost.

18. The metamaterial coupled recite in claim 16, wherein the transmission line comprises a series of tank circuits to provide the voltage boost.

19. A metamaterial coupled antenna, comprising:
a metamaterial configured to generate a spoof surface plasmon in the presence of heat; and
a rectenna, the rectenna comprising:
an antenna element that resonates when the generated spoof surface plasmon has a frequency in the terahertz range; and
a diode coupled to the antenna element over the transmission line to receive the voltage signal and rectify the voltage signal to produce electricity; and
a transmission line to carry the voltage signal from the antenna element to the diode for rectification , wherein the transmission line is configured to provide a voltage boost to the voltage signal delivered to the diode.

20. The metamaterial coupled antenna recited in claim 19, wherein the diode is a MIIM diode.

21. The metamaterial coupled antenna recited in claim 20, wherein the MIIM diode comprises in a stacked configuration with a metal sandwiching two insulators.

22. The metamaterial coupled antenna recited in claim 19, wherein the metamaterial comprises a plurality of holes, wherein the antenna element is placed over a hole in the metamaterial, further comprising a reflector to confine radiation in the vertical direction.

23. The metamaterial coupled antenna recited in claim 22, wherein the reflector comprises a metal layer.

24. The metamaterial coupled antenna recited in claim 22, wherein the reflector comprises a DBR reflector.

25. The metamaterial coupled antenna recited in claim 19, wherein the transmission line is configured to compensate for diode capacitance.
